(19) United States
(12) Patent Application Publication
(10) Pub. No.: US 2009/0253071 A1
(43) Pub. Date: Oct. 8, 2009

(54) PLANOGRAPHIC PRINTING PLATE PRECURSOR

(75) Inventor: Ikuo KAWAUCHI, Shizuoka-ken (JP)

Correspondence Address: Moss & Burke, PLLC, 401 Holland Lane, Suite 407, Alexandria, VA, 22314, US

(73) Assignee: FUJIFILM CORPORATION, Tokyo (JP)

(21) Appl. No.: 12/414,676

(22) Filed: Mar. 31, 2009

(30) Foreign Application Priority Data
Apr. 2, 2008 (JP) 2008-096200

(51) Int. Cl. G03F 7/039

(52) U.S. Cl. 430/270.1

(57) ABSTRACT

A planographic printing plate precursor comprising a hydrophilic support having a surface roughness (Ra) in a range of from 0.45 to 0.60, and, on the support, a recording layer containing a phenolic resin, an infrared absorber and a polymer having at least one selected from the group consisting of a structural unit represented by the following formula (I) and a structural unit represented by the following formula (II). In the Formulae (I) and (II), R¹ represents a hydrogen atom or an alkyl group; z represents —O— or —NR²— wherein R² represents a hydrogen atom, an alkyl group, an alkenyl group or an alkynyl group; Ar¹ and Ar² each independently represent an aromatic group, and at least one of Ar¹ and Ar² represents a heteroaromatic group; and a and b each independently represent 0 or 1.

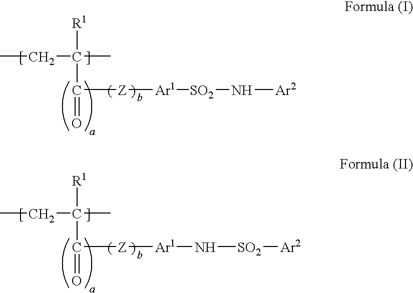

### CROSS-REFERENCE TO RELATED APPLICATION

This application claims priority under 35 USC 119 from Japanese Patent Application No. 2008-096200, the disclosure of which is incorporated by reference herein.

### BACKGROUND OF THE INVENTION

1. Field of the Invention

The present invention relates to a planographic printing plate precursor. More specifically, the invention relates to an infrared laser-sensitive positive-working planographic printing plate precursor for so called direct plate making, from which a printing plate can be directly formed based on digital signals from a computer or the like.

2. Description of the Related Art

The development of lasers in recent years has been remarkable. In particular, high-power, small-sized solid lasers and semiconductor lasers that emit near-infrared and infrared rays have become easily obtainable. These lasers are very useful as exposure light sources when forming printing plates directly from digital data from computers or the like.

The infrared laser-sensitive positive-working planographic printing plate precursor contains, as essential components, a binder resin soluble in an aqueous alkaline solution, and an infrared ray-absorption dye (IR dye) and the like which generate heat upon light absorption. The infrared light absorption dye and the like interact with the binder resin in an unexposed area (image area) so as to function as a dissolution inhibitor which can substantially reduce the solubility of the binder resin. On the other hand, in an exposed area (non-image area), the interaction of the infrared ray absorption dye and the like with the binder resin is weakened due to the heat generated, so that exposed area is dissolved in an alkaline developer, and a planographic printing plate is produced.

However, in such an infrared laser-sensitive positive-working planographic printing plate precursor, difference between the resistance to dissolution of an unexposed area (image area) in a developer and the solubility of an exposed area (non-image area) in the developer in various use conditions is still insufficient, and there is a problem in that overdevelopment or underdevelopment tends to occur due to fluctuation of use conditions. Further, even when the surface condition of an infrared laser-sensitive positive-working planographic printing plate precursor fluctuates slightly by touching the surface thereof, when handling the plate precursor, an unexposed area (image area) is dissolved by development to generate scar-like marks, resulting in causing a problem in that the printing durability of the printing plate deteriorates and the ink-acceptability thereof becomes worsen.

Such problems result from fundamental differences in plate-making mechanisms between an infrared laser-sensitive positive-working planographic printing plate precursor from which a printing plate is formed by exposure to infrared light and a positive-working planographic printing plate precursor material from which a printing plate is formed by exposure to ultraviolet rays. That is, the positive-working planographic printing plate used for plate-making by exposure to UV light includes a binder resin soluble in an aqueous alkali solution, an onium salt and a quinone diazide compounds as essential ingredients. The onium salt and quinone diazide compounds act not only as a dissolution inhibitor due to an interaction with the binder resin, in a light-unexposed area (image area), but, in light-exposed area (non-image area), act as a dissolution accelerator by generating an acid due to decomposition with light. That is, the onium salt and quinone diazide compound play the two roles.

On the other hand, in the infrared laser-sensitive positive-working planographic printing plate precursor, the infrared absorption dye and the like function only as a dissolution inhibitor of unexposed portions (image portions), and does not promote the dissolution of an exposed area (non-image area). Therefore, in order to distinguish between the solubility of the unexposed area from that of the exposed area in the infrared laser-sensitive positive-working planographic printing plate precursor, it is inevitable that a material which has a high solubility originally in an alkaline developer is used as the binder resin, resulting in an unstable state of the plate precursor before being developed. Furthermore, in order to form an ink-receptive recording layer on a hydrophilic support of such a planographic printing plate precursor, it is problematic that adhesiveness at the interface between the recording layer and the support may become unstable, which may result in exerting an adverse effect on printing durability of an unexposed area (image area) of a planographic printing plate formed therefrom, and in particular, significantly problematic with the reproducibility of images having a small image area, such as thin lines or dots. In recent years, a higher image resolution has been demanded. In order to cope with such demands, improvement on the image reproducibility with a high definition exposure is also demanded.

Various proposals have been made to address the above problems. For example, a method has been proposed in which the distribution of an infrared absorber is localized in the layer to improve the discrimination of an image (see, for example, the publication of Japanese Patent Application Laid-Open (JP-A) No. 2001-281856). Although there is improvement in the discrimination is recognizable to some degree with this method, there is still room for improvement from the viewpoint of the thin line reproducibility.

For the purpose of improving the removability of an exposed area, a planographic printing plate precursor having a recording layer having a multilayer structure has been proposed in which a lower layer that contains a polymer having a structural unit having —NH— and —SO₂— groups at the side chain thereof and a heat-sensitive upper layer that contains a phenolic resin and an infrared absorber are provided on a hydrophilic substrate in this order (see, for example, EP No. 1826001-A1).

In addition, from the viewpoint of enhancing the printing durability and resistance to solvent, a method of blending a polymer different from the polymer in the lower layer of a recording layer having a multilayer structure has been proposed (see, for example, JP-A No. 2005-242241).

In such image recording layers having a multilayer structure, the use of a resin having an excellent alkali solubility in a lower layer exerts an effect of rapidly removing undesirable layer residues, which is a problem of a positive-working image forming layer responsive to an infrared laser, and exerts an effect of improving image formability since the lower layer functions as a thermally insulative layer and effectively inhibits thermal diffusion to a substrate. However, formation of the recording layer having such a multilayer structure necessitates selection of resins having properties which are different from each other as the resins used in each layer for forming the recording layer, which results in causing a problem in that the interaction between the resins is weakened or a problem in that a so-called side edge where the lower layer in the unexposed area is eluted from the interface with a developer attributable to the good developability of the lower layer. At present, in particular, there is a high demand for improvement of reproducibility of small-area images such as fine lines, at the time of high-definition exposure (resolution).

### SUMMARY

The present invention has been made in view of the above circumstances and provides an ink composition, an ink set, and an image recording method.

A first aspect of the invention provides a planographic printing plate precursor comprising a hydrophilic support having a surface roughness (Ra) in a range of from 0.45 to 0.60, and, on the support, a recording layer containing a phenolic resin, an infrared absorber and a polymer having at least one selected from the group consisting of a structural unit represented by the following formula (I) and a structural unit represented by the following formula (II):

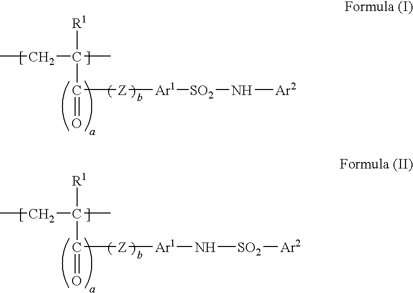

wherein, in formula (I) and formula (II): R¹ represents a hydrogen atom or an alkyl group; z represents —O— or —NR²— wherein R² represents a hydrogen atom, an alkyl group, an alkenyl group or an alkynyl group; Ar¹ and Ar² each independently represent an aromatic group, and at least one of Ar¹ and Ar² represents a heteroaromatic group; and a and b each independently represent 0 or 1.

### BRIEF DESCRIPTION OF THE DRAWINGS

FIG. 1 is a graph of one example of an alternating current waveform used for an electrochemical surface roughening treatment applied for the preparation of a support of a planographic printing plate precursor in the examples.

FIG. 2 is a side view of one example of a radial-type cell used for the electrochemical surface roughening treatment with the alternating current waveform used for the preparation of a support of a planographic printing plate precursor in the examples.

### DETAILED DESCRIPTION OF THE INVENTION

According to an aspect of the present invention, there is provided a planographic printing plate precursor comprising a hydrophilic support having a surface roughness (Ra) in a range of from 0.45 to 0.60, and, on the support, a recording layer containing a phenolic resin, an infrared absorber and a polymer having at least one selected from the group consisting of a structural unit represented by the following formula (I) and a structural unit represented by the following formula (II).

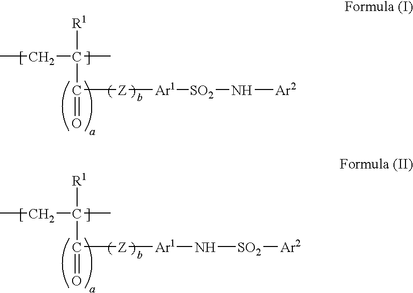

In Formulae (I) and (II), R¹ represents a hydrogen atom or an alkyl group; z represents —O— or —NR²— wherein R² represents a hydrogen atom, an alkyl group, an alkenyl group or an alkynyl group; Ar¹ and Ar² each independently represent an aromatic group, and at least one of Ar¹ and Ar² represents a heteroaromatic group; and a and b each independently represent 0 or 1.
R¹, R², Ar¹ and Ar² may further have a substituent, respectively.

The recording layer of the planographic printing plate precursor of the invention may have a single layer structure, but has preferably a multiple layer structure having at least two layers including an lower recording layer which is provided in the closest proximity to a support, and contains a polymer having at least one selected from the group consisting of a structural unit represented by the above formula (I) and a structural unit represented by the above formula (II), and an upper recording layer which contains a phenolic resin and an infrared absorber, and increases in the solubility of the layer in an aqueous alkaline solution upon exposure to infrared laser beam.

Here, it is preferable that the lower recording layer further contains an alkali-soluble polymer which has a slower dissolution speed in an aqueous alkaline solution than that of the polymer having at least one selected from the group consisting of a structural unit represented by the above formula (I) and a structural unit represented by the above formula (II), and which is incompatible with the specific polymer, thereby forming a dispersion phase containing the two kinds of polymers which are mutually incompatible with each other.

Here, it is preferable that the ratio by weight of the polymer having at least one selected from the structural unit represented by the formula (I) and the structural unit represented by the formula (II) and the alkali-soluble polymer incompatible with the polymer is in the range of from 95:5 to 60:4. Such an alkali-soluble polymer incompatible with the specific polymer is preferably a novolak resin.

According to the above constitution of the invention, the specific polymer which is an alkali-soluble polymer contained in the recording layer provided in the closest proximity to the surface of the support is excellent in resistance to an alkaline developer and resistance to chemicals, so that the permeability of an aqueous alkaline solution into the recording layer, in particular, permeation from the verge side (edge side) of an image portion can be effectively prevented. In the invention, the effect of the specific surface roughness of the support is synergized with the above effect, so that the adhesiveness between the support and the recording layer can be improved, and the dissolution of an image portion in the cross-sectional direction can be suppressed by the protrusions of the grained surface, and therefore, damages of the image portion in an aqueous alkaline solution can be suppressed.

Further, the image portion has an excellent adhesiveness to the support, and a good image reproducibility can be obtained, so that such an effect can be particularly exerted on a small area image such as dots and thin lines, and it is considered that effects such as an excellent reproducibility of a high definition image, a good printing durability and a high resistance to a developer of the small area image can be exerted.

Furthermore, it can be presumed that the specific polymer exhibits an excellent resistance to dissolution of the recording layer in an organic solvent, so that the recording layer is not susceptible to damages due to a plate cleaner and the like.

The planographic printing plate precursor of the invention has the above recording layers on a hydrophilic support having the specific surface roughness, in which in addition to the single layered recording layer or the multiple layered recording layer, other layers such as a surface protective layer, an undercoat layer and a backcoat layer may be optionally provided, unless the effect of the invention is impaired.

The properties in relation to the invention are particularly remarkable in a high definition image having a small image area. For this reason, the planographic printing plate precursor of the invention is particularly useful in formation of a high definition image using a high resolution exposure apparatus, for example, PT-R SERIES (trade name, manufactured by Dainippon Screen Mfg. Co., Ltd.), TRENDSETTER UHR (trade name, manufactured by KGC) and is also useful in formation of a high definition image using, for example, an FM screen with an increase in use with recent CTP application, and can be preferably used in image formation using commercially available FM screens such as STACCATO (trade name, manufactured by KGC), FAIRDOT, RANDOT (both trade names, manufactured by Dainippon Screen Mfg. Co., Ltd.), Co-Re SCREEN or TAFFETA (both are trade names, manufactured by FUJIFILM Corporation).

Hereinafter, the planographic printing plate precursor of the invention will be described in detail.

The planographic printing plate precursor of the invention comprises a hydrophilic support having a surface roughness (Ra) in the range of from 0.45 to 0.60, and a recording layer containing a polymer having at least one selected from the group consisting of a structural unit represented by the following formula (I) and a structural unit represented by the following formula (II), and a phenolic resin and an infrared absorber on the support.

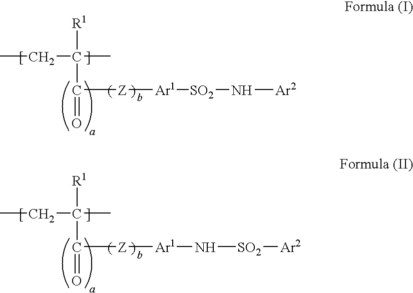

In Formulae (I) and (II), R¹ represents a hydrogen atom or an alkyl group; Z represents —O— or —NR²—; R² represents a hydrogen atom, an alkyl group, an alkenyl group, or a alkynyl group; Ar¹ and Ar² each independently represent an aromatic group, at least one of Ar¹ and Ar² is a hetero-aromatic group; and a and b each independently represent 0 or 1.
R¹, A², Ar¹ and Ar² may further have a substituent, respectively.

Hereinafter, the constitutional elements of the invention will be described successively

### [Recording Layer]

The recording layer of the planographic printing plate precursor of the invention contains a polymer (specific polymer) having at least one selected from the group consisting of a structural unit represented by the following formula (I) and a structural unit represented by the following formula (II), and a phenolic resin and an infrared absorber.

### <Specific Polymer>

The specific polymer is described below in detail.

The specific polymer in the invention is a polymer having at least one selected from the group consisting of a structural unit represented by the following Formula (I) and a structural unit represented by the following Formula (II).

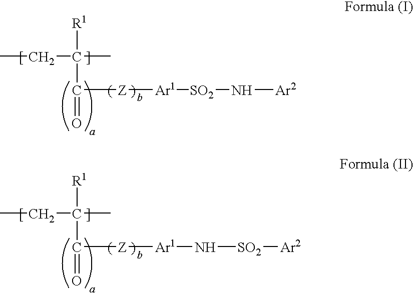

In Formulae (I) and (II), R¹ represents a hydrogen atom or an alkyl group; Z represents —O— or —NR²— wherein R² represents a hydrogen atom, an alkyl group, an alkenyl group or an alkynyl group; Ar¹ and Ar² each independently represent an aromatic group, at least one of Ar¹ and Ar² is a hetero-aromatic group; and a and b each independently represent 0 or 1.

In Formula (I), R¹ represents a hydrogen atom or an alkyl group, wherein the alkyl group is a substituted or unsubstituted alkyl group, and is preferably an unsubstituted alkyl group. Examples of the alkyl group represented by R¹ include lower alkyl groups, such as a methyl group, an ethyl group, a propyl group and a butyl group. It is preferable that R¹ is a hydrogen atom or a methyl group.

Z represents —O— or —NR²—, and is preferably —NR—. Herein, R² represents a hydrogen atom, a substituted or unsubstituted alkyl group, a substituted or unsubstituted alkenyl group, or a substituted or unsubstituted alkynyl group. R² is preferably a hydrogen atom or an unsubstituted alkyl group, and more preferably a hydrogen atom.

a and b each independently represent 0 or 1. The case where a is 0 and b is 1 is preferable, the case where both a and b are 0 is more preferable, and the case where both a and b are 1 is still more preferable.

More specifically, when a is 0 and b is 1, Z is preferably —O—. When both a and b are 1, Z is preferably —NR²—, and in this case, R² is preferably a hydrogen atom.

Ar¹ and Ar² each independently represent an aromatic group, and at least one of Ar¹ and Ar² is a hetero-aromatic group. Ar¹ is a divalent aromatic group, and Ar² is a monovalent aromatic group. These aromatic groups each are a substituent formed by substituting one or two linkage groups for one or two hydrogen atoms as constituents of the aromatic ring.

Such an aromatic ring may be selected from among hydrocarbon aromatic rings including benzene, naphthalene and anthracene, or it may be selected from among hetero-aromatic rings including furan, thiophene, pyrrole, imidazole, 1,2,3-triazole, 1,2,4-triazole, tetrazole, oxazole, isooxazole, thiazole, isothiazole, thiadiazole, oxadiazole, pyridine, pyridazine, pyrimidine, pyrazine, 1,3,5-triazine, 1,2,4-triazine and 1,2,3-triazine.

In addition, the aromatic ring may be a fused ring formed by fusing two or more of those rings together, such as benzofuran, benzothiophene, indole, indazole, benzoxazole, quinoline, quinazoline, benzimidazole and benzotriazole.

These aromatic or hetero-aromatic groups may further have a substituent, and examples of substituents which can be introduced into aromatic or hetero-aromatic groups include an alkyl group, a cycloalkyl group, an alkenyl group, a cycloalkenyl group, an aryl group, a heteroaryl group, a hydroxyl group, —SH, a carboxylic acid group or alkyl esters thereof, a sulfonic acid group and alkyl esters thereof, a phosphinic acid group and alkyl esters thereof, an amino group, a sulfonamide group, an amido group, a nitro group, a halogen atom, and substituents formed by two or more of these groups being linked together. These substituents may be substituents further having any of the substituents as recited above.

Ar² is preferably a hetero-aromatic group which may have a substituent, more preferably a nitrogen-containing heteroaromatic ring selected from pyridine, pyridazine, pyrimidine, pyrazine, 1,3,5-triazine, 1,2,4-triazine, 1,2,3-triazine, tetrazole, oxazole, isooxazole, thiazole, isothiazole, thiadiazole, oxadiazole or the like.

Examples of a monomer capable of forming the structural unit represented by Formula (I) or Formula (II) (Exemplified monomers (1) to (27)) are illustrated below, but these examples should not be construed as limiting the scope of the invention. Of the exemplified monomers illustrated below, monomers having the linkage group —SO₂—NH— from the main chain side (e.g., Monomer (1)) are those which can be converted into the structural units represented by Formula (I), and monomers having the linkage group —NH—SO₂— (e.g., Monomer (12)) are those which can be converted into the structural units represented by Formula (II).

Monomers (1) to (6)

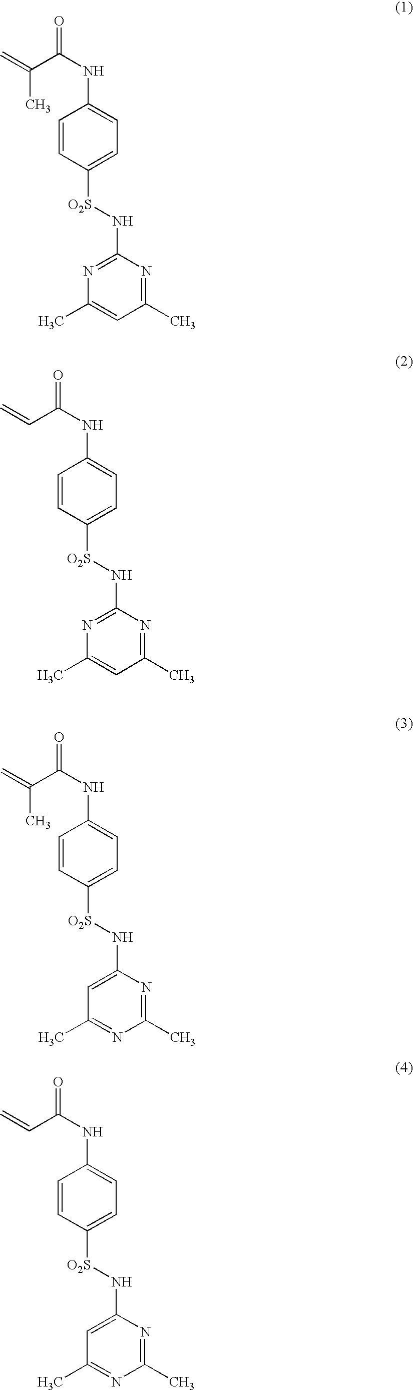

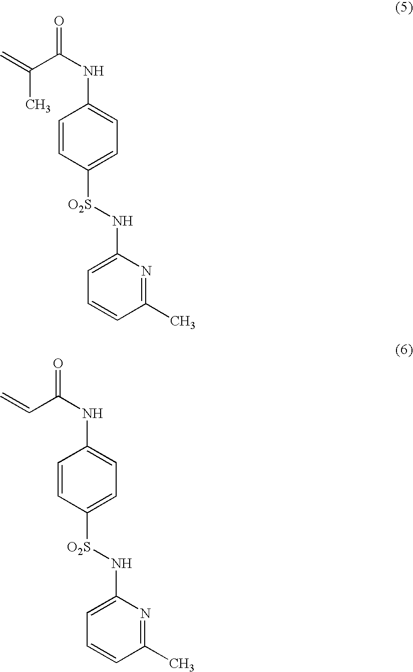

Monomers (7) to (12)

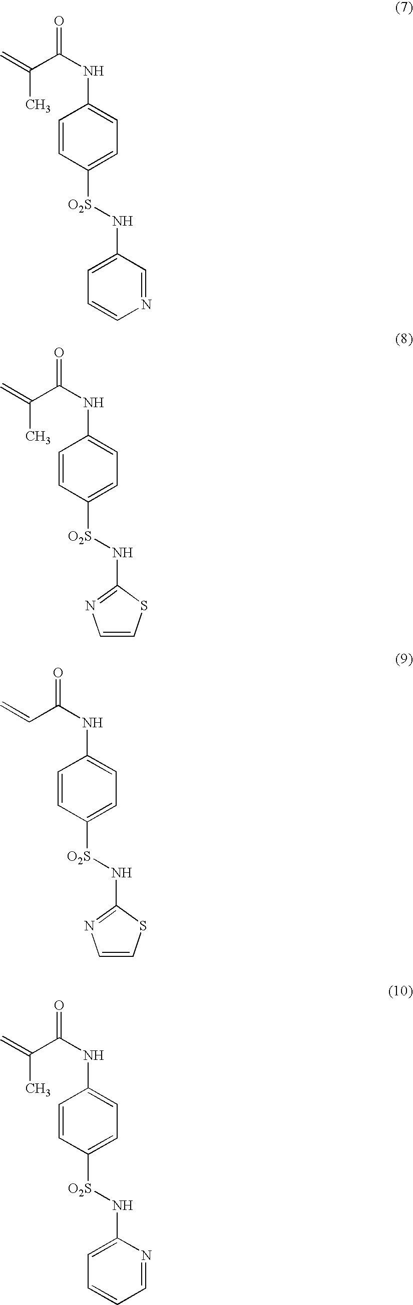

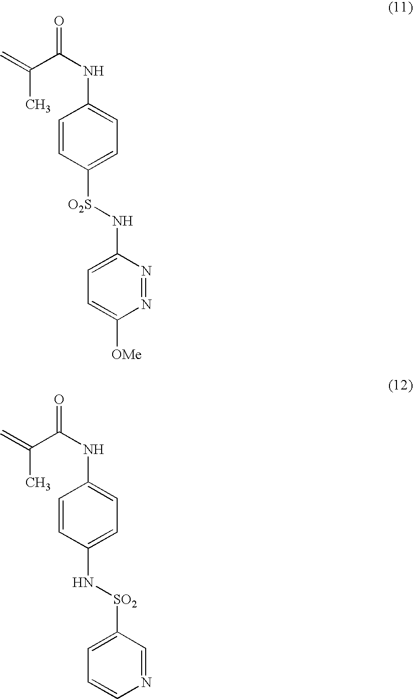

Monomers (13) to (18)

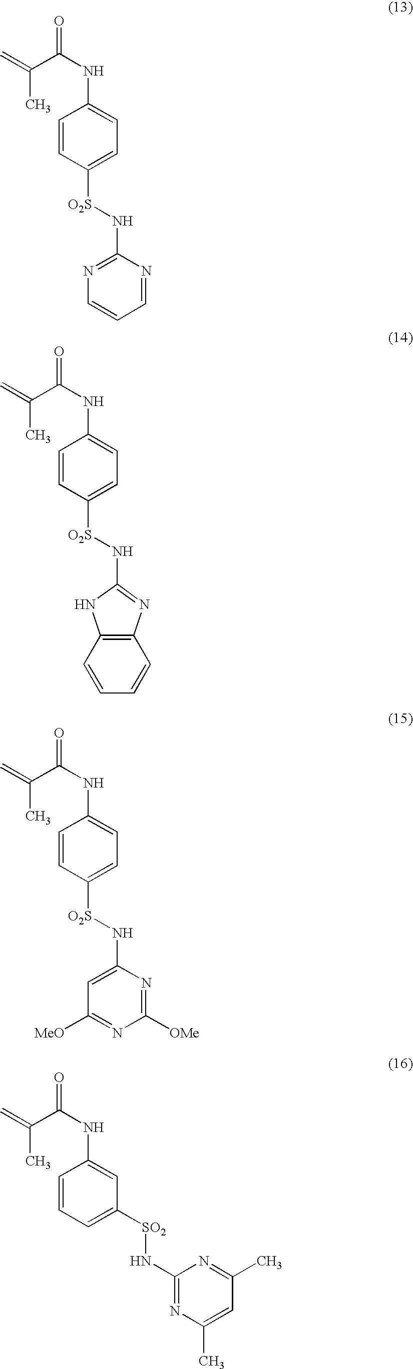

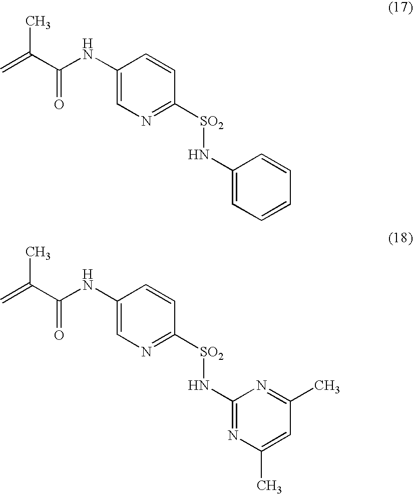

Monomers (19) to (24)

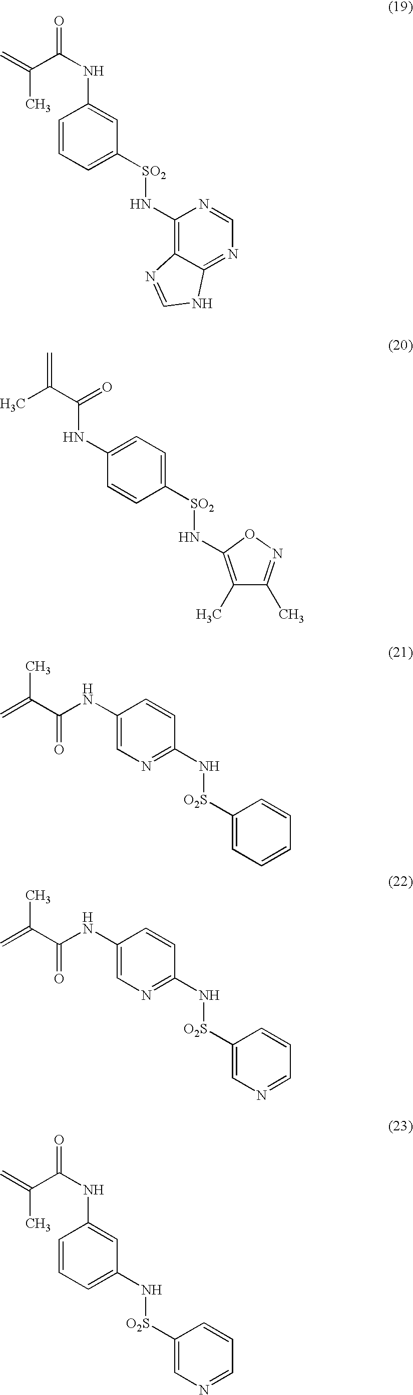

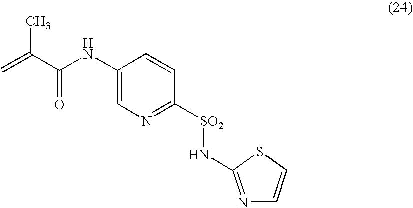

Monomers (25) to (27)

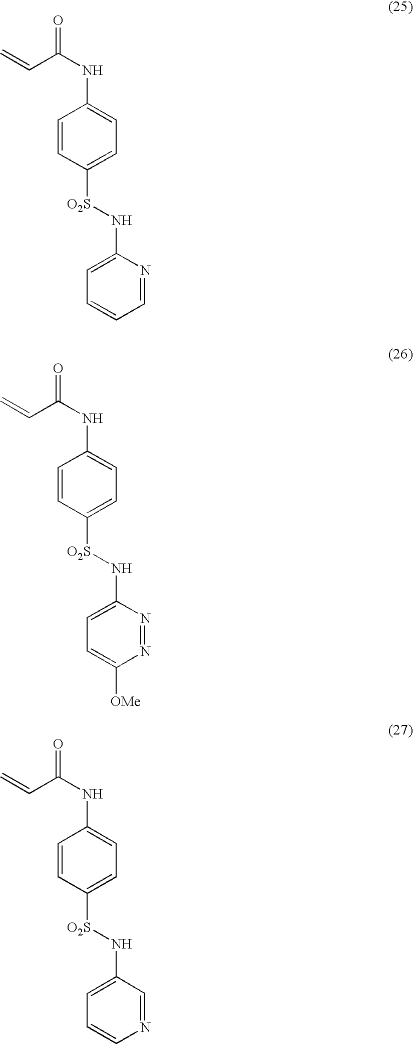

The specific polymer is an alkali-soluble polymer containing structural units represented by Formula (I) or Formula (II), and the structural units contained in the specific polymer and represented by Formula (I) or Formula (II) may be of only one kind or a combination of two or more kinds.

The content of structural units represented by Formula (I) or Formula (II) is preferably from 10 to 100 mole %, more preferably from 20 to 90 mole %, still more preferably from 30 to 80 mole %, and particularly preferably from 30 to 70 mole %.

The specific polymer containing those structural units may be a copolymer containing other structural units in addition to the structural units represented by Formula (I) or Formula (II).

Examples of the other structural units include structural units derived from hydrophobic monomers having substituents such as an alkyl group and an aryl group in their respective side chain structures, and those derived from hydrophilic monomers having substituents such as an acidic group, an amido group, a hydroxyl group and an ethylene oxide group in their respective side chain structures. Although monomers to be copolymerized can be optionally selected from those monomers in accordance with the intended use, the selection of monomer species for copolymerization may be made to the extent of exerting no adverse effect on alkali solubility of the specific polymer.

Examples of other copolymerization components usable in synthesis of the specific polymer according to the invention include (meth)acrylamide, N-substituted (meth)acrylamides, N-substituted maleimides, (meth)acrylic esters, (meth)acrylic esters having polyoxyethylene chains, 2-hydroxyethyl(meth)acrylate, styrene, styrenesulfonic acid, o-, p- or m-vinylbenzene acids, vinylpyridine, N-vinylcaprolactam, N-vinylpyrrolidine, (meth)acrylic acid, itaconic acid, maleic acid, glycidyl(meth)acrylate, hydrolyzable vinyl acetate and vinylphosphonic acid. Of these compounds, N-benzyl(meth)acrylamide and (meth)acrylic acid can be used as preferred copolymerization components.

The number average molecular weight (Mn) of the specific polymer is preferably from 10,000 to 500,000, more preferably from 10,000 to 200,000, and still more preferably from 10,000 to 100,000. And the weight average molecular weight (Mw) is preferably from 10,000 to 1000,000, more preferably from 20,000 to 500,000, and still more preferably from 20,000 to 200,000. These molecular weight measurements are described in detail in “Examples” section in this specification.

Examples of a suitable structure of the specific polymer usable in the invention are illustrated below with their individual combinations of structural units.

Copolymers (1) to (3)

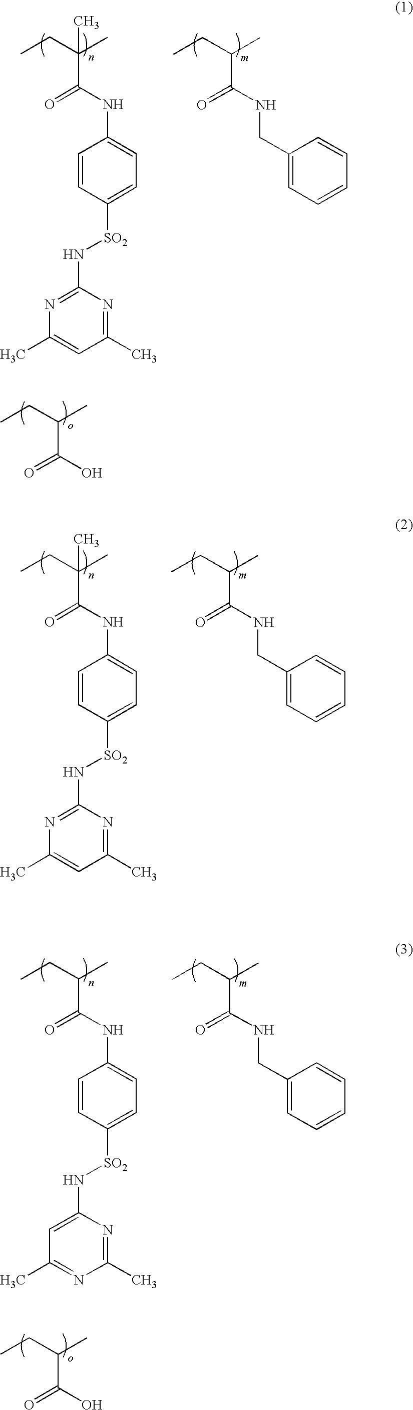

Copolymers (4) to (6)

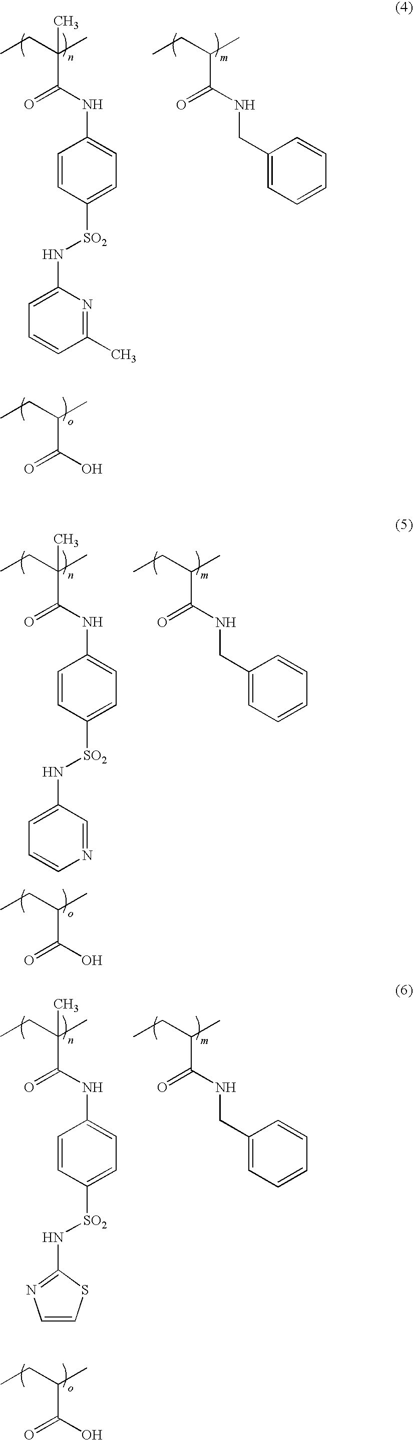

Copolymers (7) to (9)

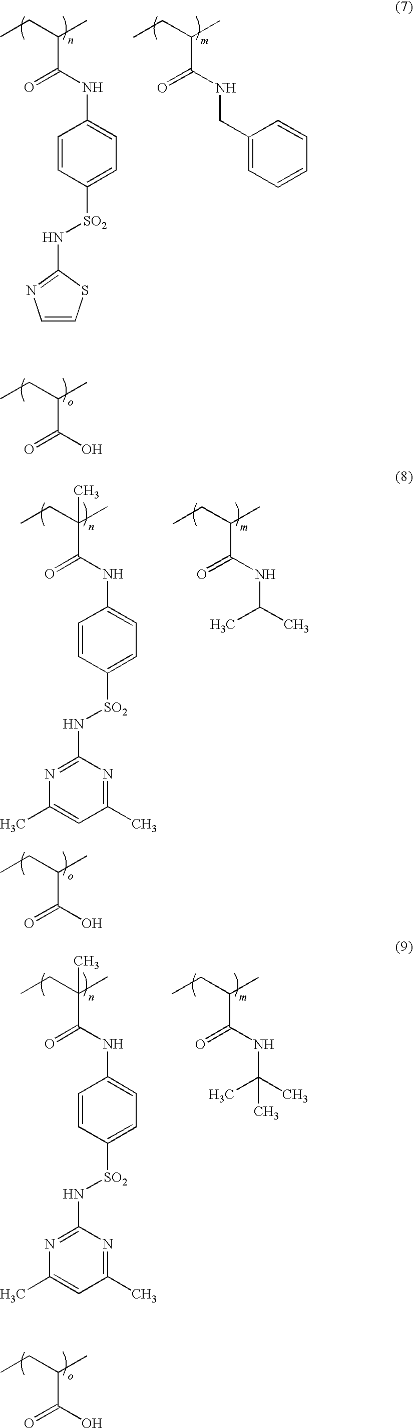

Copolymers (10) to (12)

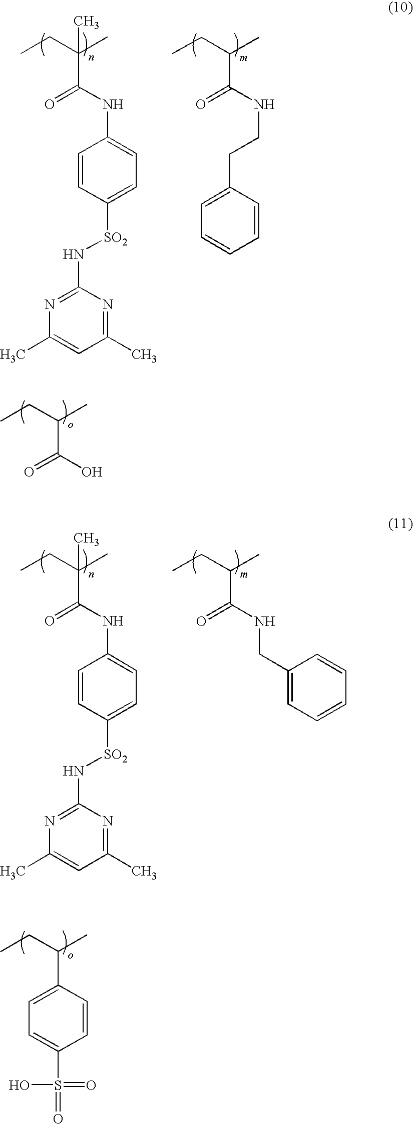

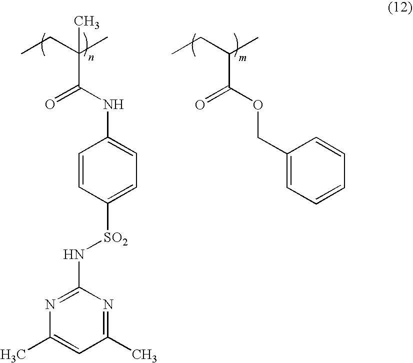

Copolymers (13) to (15)

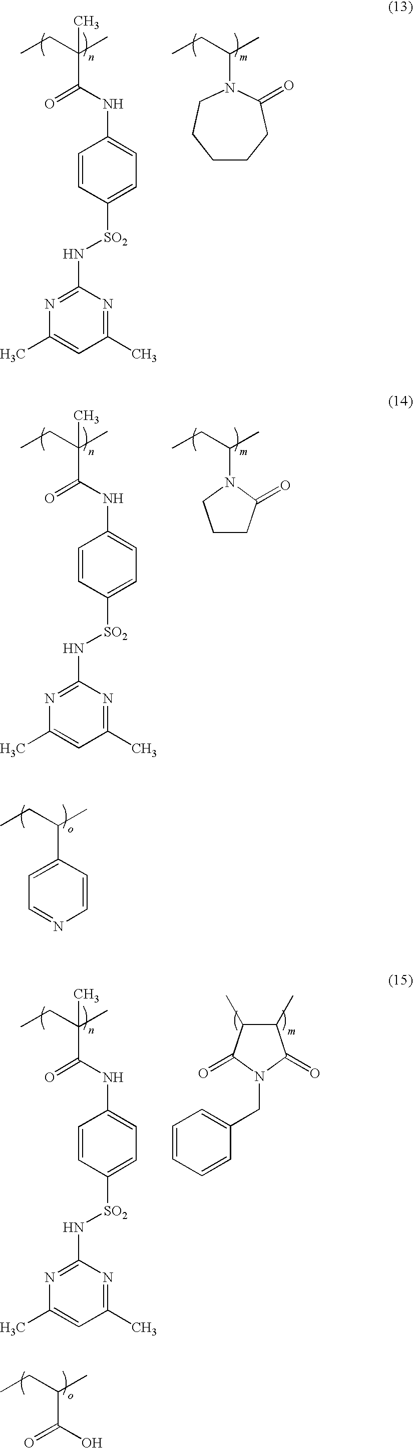

Copolymers (16) to (18)

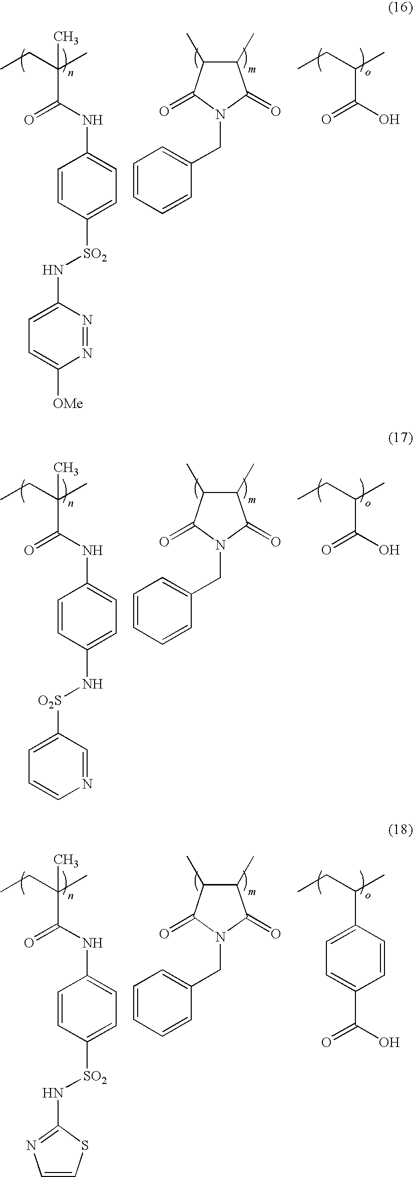

Copolymers (19) to (20)

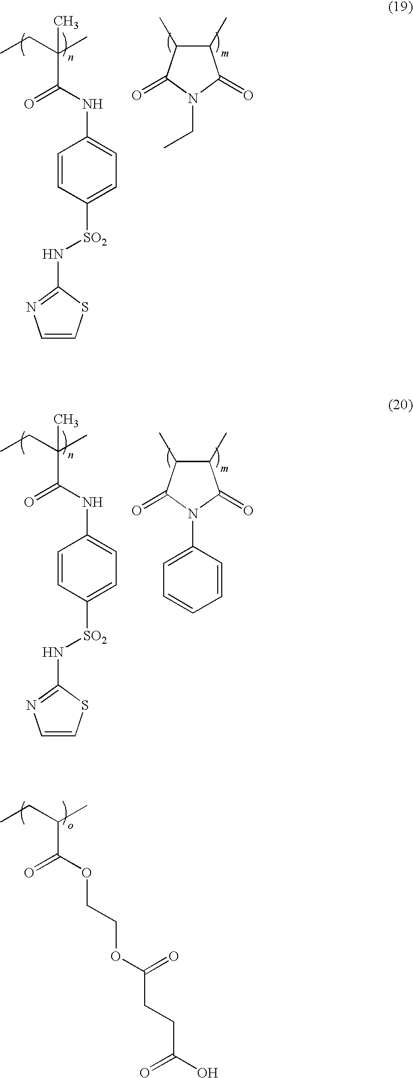

Copolymer (21): Copolymer (15)-modified compound, wherein the structural unit derived from N-(4-hydroxy-3,5-dimethyl-benzylacrylamide) is substituted for the structural unit derived from acrylic acid in Copolymer (15).

In each of Copolymers (1) to (21), letters m, n and o represent molar polymerization proportions of their corresponding structural units, and it is preferable that n is from 10 to 90 mole %, m is from 5 to 80 mole % and o is from 0 to 50 mole %, provided, m+n+o=100.

Examples of the specific polymer relating to the invention are illustrated below with monomers as starting materials (copolymerizable monomer) and their molar polymerization proportions, but these examples should not be construed as limiting the scope of the invention. Incidentally, the specific polymers formed from these monomers and relating to the invention are referred to as Specific Polymer (1) to Specific Polymer (8).

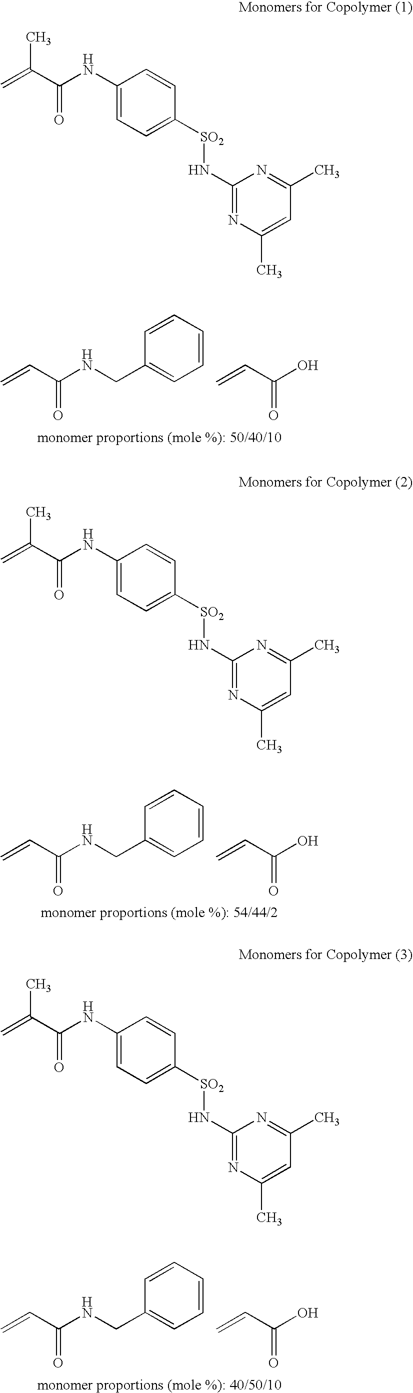

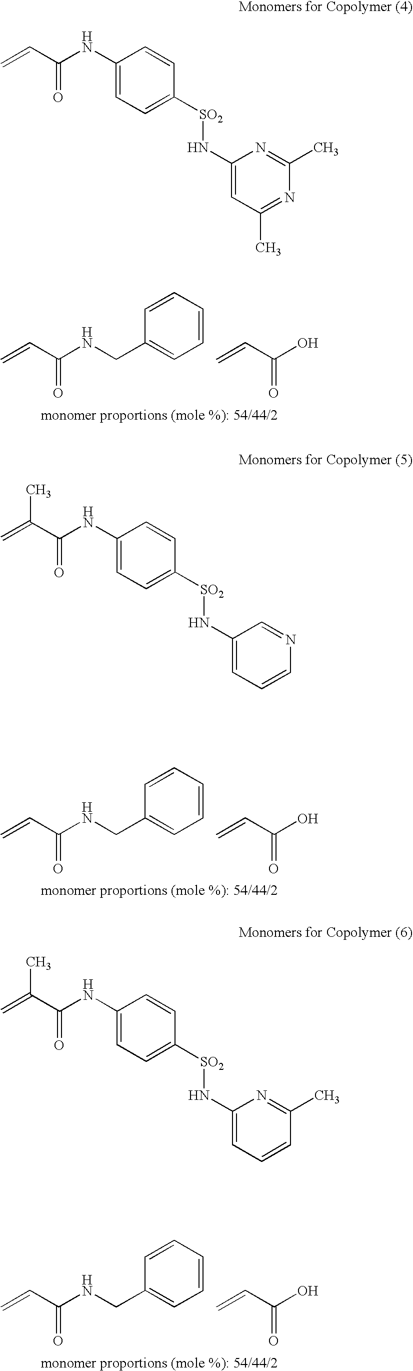

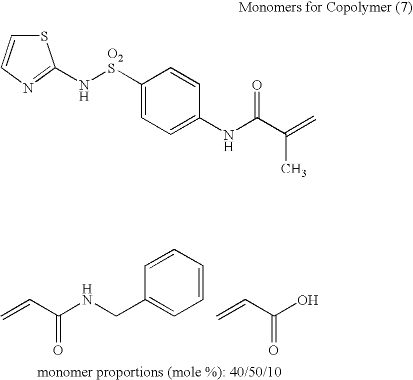

### Monomers for Copolymer (8)

Exemplified Monomer (1)/N-(4-hydroxy-3,5-dimethyl-benzylacrylamide)/N-benzylmaleimide monomer proportions (mole %): 33.8/35/31.2

The content of the specific polymer in the recording layer is preferably from 5 mass % to 95 mass % and more preferably 10 mass % to 90 mass % relative to the total solid content of the recording layer.

Here, when the recording layer of the invention is a multiple layer structure, the specific polymer is preferably contained in the lower recording layer provided in the closest proximity of the support, and when such a structure is formed, the content of the specific polymer in the lower recording layer is preferably from 40 mass % to 95 mass % and more preferably from 50 mass % to 95 mass % relative to the total solid content of the lower recording layer.

The constitutional elements of the invention will be described in more detail. The recording layer of the invention is a positive recording layer whose solubility in an alkaline developer is increased in a light-exposed area. The positive recording layer contains the specific polymer, an alkali-soluble phenolic resin and an infrared absorber, and the infrared absorber functions as a compound for suppressing the alkali solubility of the alkali-soluble polymer compound. Accordingly, the solubility-suppressing capability in the light-exposed area is lost due to exposure to infrared laser beam, so that the solubility in the alkaline developer increases, thereby forming an image.

In the invention, the water-insoluble and aqueous alkali-soluble polymer compound (hereinafter referred to as an “alkali-soluble polymer” as required) which is used in plural positive-working recording layers includes homopolymers having an acidic group on a main chain and/or a side chain thereof, copolymers having an acidic group on a main chain and/or a side chain thereof, and mixtures of these polymers. Accordingly, the polymer layer according to the invention has the characteristics that it is dissolved when being brought into contact with an alkali developer. The scope of the alkali-soluble polymer contained in the lower recording layer in the planographic printing plate precursor of the invention includes the specific polymer.

<Phenolic Resin>

The recording layer of the invention contains a phenolic resin. The phenolic resin is a polymer compound having a phenolic hydroxyl group as an alkali-soluble group in the molecule.

Examples of the polymer compounds having a phenolic hydroxyl group include novolak resin such as phenol-formaldehyde resin m-cresol-formaldehyde resin, p-cresol-formaldehyde resin, m-/p-mixed cresol-formaldehyde resin, and phenol/cresol (m-, p-, or m-/p-mixture)-formaldehyde resin and a pyrogallol-acetone resin. As the polymer compound having a phenolic hydroxyl group, it is preferable to use polymer compounds having a phenolic hydroxyl group at the side chain thereof in addition to the above compounds. Examples of the polymer compound having a phenolic hydroxyl group at the side chain thereof include polymer compounds obtained by homopolymerizing a polymerizable monomer containing a low-molecular weight compound having one or more phenolic hydroxyl groups and one or more polymerizable unsaturated bonds, or copolymerizing the monomer with other polymerizable monomers.

Examples of the polymerizable monomer having a phenolic hydroxyl group include acrylamides, methacrylamides, acrylic esters, methacrylic esters and hydroxystyrenes each having a phenolic hydroxyl group. Specific examples of the polymerizable monomer which may be preferably used include N-(2-hydroxyphenyl)acrylamide, N-(3-hydroxyphenyl)acrylamide, N-(4-hydroxyphenyl)acrylamide, N-(2-hydroxyphenyl)methacrylamide, N-(3-hydroxyphenyl)methacrylamide, N-(4-hydroxyphenyl)methacrylamide, o-hydroxyphenylacrylate, m-hydroxyphenylacrylate, p-hydroxyphenylacrylate, o-hydroxyphenylmethacrylate, m-hydroxyphenylmethacrylate, p-hydroxyphenylmethacrylate, o-hydroxystyrene, m-hydroxystyrene, p-hydroxystyrene, 2-(2-hydroxyphenyl)ethylacrylate, 2-(3-hydroxyphenyl)ethylacrylate, 2-(4-hydroxyphenyl)ethylacrylate, 2-(2-hydroxyphenyl)ethylmethacrylate, 2-(3-hydroxyphenyl)ethylmethacrylate and 2-(4-hydroxyphenyl)ethylmethacrylate. Moreover, condensation polymers of phenol and formaldehyde having an alkyl group having 3 to 8 carbon atoms as a substituent such as a t-butylphenol formaldehyde resin and octylphenol formaldehyde resin as described in the specification of U.S. Pat. No. 4,123,279 may be used together.

Examples of monomer components copolymerizable with the polymerizable monomer having a phenolic hydroxyl group include compounds exemplified in (m1)-(m12), which will be described hereinafter in the other alkali-soluble polymer.

Examples of such a phenolic resin include condensation-polymerized compounds of a phenol and a formaldehyde having an alkyl group having 3-8 carbon atoms as a substituent such as t-butylphenol formaldehyde resin and octylphenol formaldehyde resin, as recited in U.S. Pat. No. 4,123,279, as preferable examples of aqueous alkali-soluble polymer compounds having a phenolic hydroxyl group of the invention.

As the synthesizing methods of the phenolic resins, conventionally known methods such as a graft copolymerization method, a block copolymerization method and a random copolymerization method may be used.

Since the phenolic resin causes a strong hydrogen bonding property in a light-unexposed area, whereas a part of the hydrogen bonds is easily released in a light-exposed area, the phenolic resin is suitable for a positive recording layer, and the phenolic resin is more preferably a novolak resin.

The phenolic resin usable for the invention has preferably a weight average molecular weight of from 500 to 20,000 and the number average molecular weight of from 200 to 10,000 measured by a GPC method.

The content of the phenolic resin in the recording layer of the invention is preferably from 3 mass % to 50 mass %, and more preferably 5 mass % to 40 mass % relative to the total solid content of the recording layer, when the recording layer has a single layer structure.

When the recording layer has a multiple layer structure, the phenolic resin is preferably contained in an upper recording layer positioned in the proximity of the surface (light-exposure surface), and in such an exemplary embodiment, the content of the phenolic resin in the recording layer of the invention is preferably from 2 mass % to 20 mass %, and more preferably 3 mass % to 15 mass % relative to the total solid content of the upper recording layer.

<Infrared Absorber>

The positive-working recording layer in the invention contains an infrared absorber that is a structural component which develops a light-to-heat converting function. This infrared absorber has the ability to convert absorbed infrared rays into heat, and the release from interaction between binder molecules, the decomposition of a developing inhibitor and the generation of an acid take place due to scanning the positive-working recording layer with laser, thereby significantly improving the solubility of the recording layer to developer. Further, there is also the case where the infrared absorber itself interacts with the alkali-soluble polymer to suppress the alkali-solubility.

When the recording layer has a multiple layer structure, such an infrared absorber may be contained in at least one of the upper recoding layer and the lower recording layer, but is preferably contained in the upper recording layer from the viewpoint of sensitivity.

In the case where such an infrared absorber is contained in the lower recording layer, when the specific polymer and another alkali-soluble polymer incompatible with the specific polymer are used in combination, it is considered that the infrared absorber is contained in the other alkali-soluble polymer which forms a dispersion phase, and the infrared absorber is localized in the dispersion phase, thereby promoting the interaction releasability, or improving the ability to decompose an acid generator when the acid generator is contained.

The infrared absorber used in the invention is dyes or pigments which efficiently absorb infrared rays having a wavelength from 760 nm to 1,200 nm and are preferably dyes or pigments having an absorption maximum in a wavelength range from 760 nm to 1,200 nm.

The infrared absorber which can be preferably used for the planographic printing plate precursor of the invention will be hereinafter explained in detail.

The dyes may be commercially available ones and known ones described in publications such as “Dye Handbook” (edited by the Society of Synthesis Organic Chemistry, Japan, and published in 1970). Specific examples thereof include azo dyes, metal complex azo dyes, pyrazolone azo dyes, naphthoquinone dyes, anthraquinone dyes, phthalocyanine dyes, carbonium dyes, quinoneimine dyes, methine dyes, cyanine dyes, squarylium dyes, pyrylium dyes, metal thiolate complexes, and the like.

Preferable examples of the dye include cyanine dyes described in JP-A Nos. 58-125246, 59-84356, 59-202829, and 60-78787; methine dyes described in JP-A Nos. 58-173696, 58-181690, and 58-194595; naphthoquinone dyes described in JP-A Nos. 58-112793, 58-224793, 59-48187, 59-73996, 60-52940, and 60-63744; squarylium dyes described in JP-A No. 58-112792; and cyanine dyes described in GB Patent No. 434,875.

Other preferable examples of the dye include near infrared absorbing sensitizers described in U.S. Pat. No. 5,156,938; substituted arylbenzo(thio)pyrylium salts described in U.S. Pat. No. 3,881,924; trimethinethiapyrylium salts described in JP-A No. 57-142645 (U.S. Pat. No. 4,327,169); pyrylium type compounds described in JP-A Nos. 58-181051, 58-220143, 59-41363, 59-84248, 59-84249, 59-146063, and 59-146061; cyanine dyes described in JP-A No. 59-216146; pentamethinethiopyrylium salts described in U.S. Pat. No. 4,283,475; and pyrylium compounds described in Japanese Patent Application Publication (JP-B) Nos. 5-13514 and 5-19702.

Preferable examples of the dye further include near infrared absorbing dyes represented by formulae (I) or (II) described in U.S. Pat. No. 4,756,993.

Among these dyes, particularly preferable are cyanine dyes, squarylium dyes, pyrylium salts, and nickel thiolate complexes.

The pigment which can be used in the invention may be commercially available pigments described in publications such as Color Index (C.I.) Handbook, “Latest Pigment Handbook” (edited by Japan Pigment Technique Association, and published in 1977), “Latest Pigment Application Technique” (by CMC Publishing Co., Ltd. in 1986), and “Printing Ink Technique” (by CMC Publishing Co., Ltd. in 1984).

Examples of the pigment include black pigments, yellow pigments, orange pigments, brown pigments, red pigments, purple pigments, blue pigments, green pigments, fluorescent pigments, metal powder pigments, and polymer-bonded dyes. Specifically, the following can be used: insoluble azo pigments, azo lake pigments, condensed azo pigments, chelate azo pigments, phthalocyanine pigments, anthraquinone pigments, perylene and perynone pigments, thioindigo pigments, quinacridone pigments, dioxazine pigments, isoindolinone pigments, quinophthalone pigments, dyeing lake pigments, azine pigments, nitroso pigments, nitro pigments, natural pigments, fluorescent pigments, inorganic pigments, and carbon black.

These pigments may be used with or without surface treatment of the pigment particles. Examples of a method of the surface treatment include a method of coating the surface of the pigment particles with resin or wax; a method of adhering a surfactant onto the surface of the pigment particles; and a method of bonding a reactive material (such as a silane coupling agent, an epoxy compound, or a polyisocyanate) to the surface of the pigment particles. The surface treatment methods are described in “Nature and Application of Metal Soap” (Saiwai Shobo), “Printing Ink Technique” (by CMC Publishing Co., Ltd. in 1984), and “Latest Pigment Application Technique” (by CMC Publishing Co., Ltd. in 1986).

The particle size of the pigment is preferably from 0.01 μm to 10 μm, more preferably from 0.05 μm to 1 μm, and even more preferably from 0. 1 μm to 1 μm from the viewpoint of the stability of a coating liquid for a recording layer and the uniformity of the coating layer to be formed.

As the method of dispersing pigment, any known dispersing techniques used to produce ink or toner can be used. Examples of a machine which can be used for the dispersing pigment include an ultrasonic disperser, a sand mill, an attriter, a pearl mill, a super mill, a ball mill, an impeller, a disperser, a KD mill, a colloid mill, a dynatron, a three-roll mill, and a pressing kneader. Details are described in “Latest Pigment Application Technique” (published by CMC Publishing Co., Ltd. in 1986).

The planographic printing plate precursor of the invention has a positive-working recording layer. The positive-working recording layer preferably contains an infrared absorber which causes an interaction with a binder polymer having a specific function group to bring about a positive-working action (the solubility of an unexposed area in an alkali developer is suppressed while an exposed area is released from the suppression of the solubility). To this end, it is particularly preferable that the infrared absorber has an onium salt structure. Specifically, among the aforementioned infrared absorbers, cyanine dyes and pyrylium salts are particularly preferable. The details of these cyanine dyes and pyrylium salts are as described above.

Moreover, an anionic infrared absorber as described in JP-A No. 11-338131 can also be preferably used. This anionic infrared absorber has an anionic structure without a cationic structure on the mother nucleus, which substantially absorbs infrared ray, of the dye.

Examples of the anionic infrared absorber include (a-1) an anionic metal complex and (a-2) an anionic phthalocyanine.

Here, the anionic metal complex (a-1) refers to a compound in which the central metal and the ligands in the complex part that substantially absorbs light form an anion as a whole.

The anionic phthalocyanine (a-2) refers to a compound in which an anionic group such as a sulfonic acid, a carboxylic acid or a phosphonic acid group as a substituent is bonded to a phthalocyanine skeleton to form an anion as a whole.

Examples further include anionic infrared absorbers represented by the formula [Ga⁻-M-Gb]ₘX^{m+} (Ga⁻ represents an anionic substituent, Gb represents a neutral substituent, and X^{m+} represents a cation having a valence of 1 to m (where m denotes an integer from 1 to 6) including a proton) as described in JP-A No. 11-338131.

The infrared absorber is preferably a dye. Preferable examples of the dye include dyes having an onium salt structure as described in JP-A No. 11-291652, paragraphs [0018] to [0034].

For the purpose of further improving the sensitivity and developing latitude, in addition to the infrared absorber such as the cyanine dye, pyrylium salt dye or anionic dye, which exhibit dissolution inhibitive ability, other dyes or pigments may be used together in the recording layer of the planographic printing plate precursor.

When the recording layer has a single layer structure, the content of the infrared absorber in the recording layer is preferably from 2 mass % to 20 mass %, and more preferably 3 mass % to 15 mass % relative to the total solid content of the recording layer. When the recording layer has a multiple layer structure, the content of the infrared absorber in the recording layer is preferably from 0.01 mass % to 50 mass %, more preferably 0.1 mass % to 20 mass %, and still more preferably 0.5 mass % to 15 mass %, relative to the total solid content for each of the lower recording layer and other recording layer, from the viewpoint of the image formability and the prevention of scumming in a non-image area.

When an infrared absorber is contained in a recording layer in which a dispersion phase is formed by using two or more kinds of polymers in combination, the infrared absorber may be contained in either a matrix phase or a dispersion phase, or may be contained in both of them. When a desired component such an initiator and an infrared absorber is contained in a latex for forming the dispersion phase, such a component may be added to a material at the time of forming latex particles, or may be introduced after the latex is formed.

As the method of introducing after the latex is formed, a method, in which a desired component such as an initiator, a dye and a crosslinking agent to be introduced in the latex in an aqueous system is dissolved in an organic solvent, and the resultant solution is added to a dispersion medium, may be exemplified.

<Other Polymers>

Other known alkali-soluble polymer may be added in the recording layer of the invention in accordance with the intended use, in addition to the specific polymer and the phenolic resin.

As known alkali-soluble polymers, a polymer compound having a functional group of either one of (1) a sulfoneamide group or (2) an active imide group in the molecule is preferable. For example, the following compounds may be exemplified, but are not limited thereto.

(1) Examples of the alkali-soluble polymer compound having a sulfonamide group include polymer compounds obtained by homopolymerizing polymerizable monomers having a sulfonamide group or by copolymerizing the monomer with other polymerizable monomers. Examples of the polymerizable monomer having a sulfonamide group include polymerizable monomers comprising a low-molecular weight compound having, in one molecule thereof, one or more sulfonamide groups —NH—SO₂— having at least one hydrogen atom bonded to the nitrogen atom, and one or more polymerizable unsaturated bonds. Among these compounds, low-molecular weight compounds having an acryloyl group, an aryl group or a vinyloxy group and a substituted or monosubstituted aminosulfonyl group or substituted sulfonylimino group are preferable.

(2) The alkali-soluble polymer compound having an active imide group is preferably those having an active imide group in its molecule. Examples of the polymer compound include polymer compounds obtained by homopolymerizing a polymerizable monomer comprising a low-molecular weight compound having one or more active imide groups and one or more polymerizable unsaturated bonds in the molecule, or by copolymerizing this monomer with other polymerizable monomers.

As such a compound, specifically, N-(p-toluenesulfonyl)methacrylamide, N-(p-toluenesulfonyl)acrylamide and the like are preferably used.

Moreover, as the alkali-soluble polymer compound of the invention, polymer compounds obtained by polymerizing two or more types among the polymerizable monomers having a phenolic hydroxyl group, polymerizable monomers having a sulfonamide group and polymerizable monomers having an active imide group; or polymer compounds obtained by copolymerizing these two or more polymerizable monomers mentioned avobe with other polymerizable monomers are preferably used. When a polymerizable monomer having a sulfonamide group and/or a polymerizable monomer having an active imide group is copolymerized with a polymerizable monomer having a phenolic hydroxyl group, the ratio by weight of these components to be compounded is preferably in a range from 50:50 to 5:95 and particularly preferably in a range from 40:60 to 10:90.

When the alkali-soluble polymer is a copolymer of the polymerizable monomer having a phenolic hydroxyl group, polymerizable monomer having a sulfonamide group or polymerizable monomer having an active imide group and other polymerizable monomers in the invention, it is preferable to contain an alkali-solubility-imparting monomer in an amount of 10 mole % or more and more preferably 20 mole % or more in view of improving the solubility to an alkali solution and the development latitude of the precursor.

Examples of the monomer component to be copolymerized with the polymerizable monomer having a phenolic hydroxyl group, the polymerizable monomer having a sulfonamide group and the polymerizable monomer having an active imide group may include, though not particularly limited to, compounds represented by the following (m1) to (m12):
(m1) acrylic esters and methacrylic esters having aliphatic hydroxyl groups such as 2-hydroxyethyl acrylate or 2-hydroxyethyl methacrylate;
(m2) alkyl acrylate such as methyl acrylate, ethyl acrylate, propyl acrylate, butyl acrylate, amyl acrylate, hexyl acrylate, octyl acrylate, benzyl acrylate, 2-chloroethyl acrylate and glycidyl acrylate;
(m3) alkyl methacrylate such as methyl methacrylate, ethyl methacrylate, propyl methacrylate, butyl methacrylate, amyl methacrylate, hexyl methacrylate, cyclohexyl methacrylate, benzyl methacrylate, 2-chloroethyl methacrylate and glycidyl methacrylate;
(m4) acrylamide or methacrylamide such as acrylamide, methacrylamide, N-methylol acrylamide, N-ethylacrylamide, N-hexylmethacrylamide, N-cyclohexylacrylamide, N-hydroxyethylacrylamide, N-phenylacrylamide, N-nitrophenylacrylamide and N-ethyl—N-phenylacxrylamide;
(m5) vinyl ethers such as ethyl vinyl ether, 2-chloroethyl vinyl ether, hydroxyethyl vinyl ether, propyl vinyl ether, butyl vinyl ether, octyl vinyl ether and phenyl vinyl ether;
(m6) vinyl esters such as vinyl acetate, vinyl chloroacetate, vinyl butylate and vinyl benzoate;
(m7) styrenes such as styrene, α-methylstyrene, methylstyrene and chloromethylstyrene;
(m8) vinyl ketones such as methyl vinyl ketone, ethyl vinyl ketone, propyl vinyl ketone and phenyl vinyl ketone
(m9) olefins such as ethylene, propylene, isobutylene, butadiene and isoprene.
(m10) N-vinylpyrrolidone, acrylonitrile and methacrylonitrile;
(m11) Unsaturated imides such as maleimide N-acryloylacrylamide, N-acetylmethacrylamide, N-propionylmethacrylamide and N-(p-chlorobenzoyl)methacrylamide; and
(m12) unsaturated carboxylic acid such as acrylic acid, methacrylic acid, maleic anhydride and itaconic acid.

The alkali-soluble polymer compound preferably has a phenolic hydroxyl group, in view of an excellent image formability by exposure with infrared laser. Examples the alkali-soluble polymer compound having a phenolic hydroxyl group include condensed copolymers of phenol and formaldehyde having an alkyl group having 3 to 8 carbon atoms as a substituent, such as tert-butylphenol formaldehyde resin and octylphenol formaldehyde resin described in U.S. Pat. No. 4,123,279.

As a method of copolymerizing the aqueous alkali-soluble polymer compound, for example, a conventionally known graft copolymerization method, block copolymerization method or random copolymerization method may be used.

As the alkali-soluble polymer used in the upper recording layer, a resin having a phenolic hydroxyl group is desirable from the viewpoint that the resin develops a strong hydrogen bonding property in an unexposed area, whereas a part of hydrogen bonds are released with ease in an exposed area. The alkali-soluble polymer is more preferably a novolak resin. The alkali-soluble polymer preferably has a weight average molecular weight of 500 to 20,000 and a number average molecular weight of 200 to 10,000.

<Constitution of Recording Layer>

When the recording layer has a single layer structure, the recording layer is preferably constituted by including a lower recording layer containing the specific polymer, and an upper recording layer which contains a phenolic resin and an infrared absorber, and increases in the solubility of the upper layer in an aqueous alkaline solution upon exposure to infrared laser beam.

In such an exemplary embodiment, it is preferable that the lower recording layer further contains an alkali-soluble polymer which has a slower dissolution speed in an aqueous alkaline solution than that of the specific polymer, and which is incompatible with the specific polymer. As such a polymer, a novolak resin is preferable.

Further, in the lower recording layer, when another alkali-soluble polymer is used in combination with the specific polymer, the other alkali-soluble polymer forms a dispersion phase in the lower recording layer by using the other alkali-soluble polymer incompatible with the specific polymer in combination. In such an exemplary embodiment, it is preferable that the content ratio (specific polymer:other polymer) of the specific polymer as a polymer for forming a matrix phase and the other alkali-soluble polymer which is used in combination with the specific polymer to form a dispersion phase is from 95:5 to 60:40 by mass ratio.

When two or more kinds of polymer compounds which are incompatible with each other are used for forming a polymer matrix phase and a dispersion phase, examples of novolak resins and other polymers which can be used as a polymer for forming the dispersion phase are described below.

Examples of the polymer compound which can be preferably used for forming the dispersion phase in the invention include copolymers having a structural unit derived from at least one of monomers corresponding to any one of the following (1) to (5), urethane polymer compounds, novolak resins, and polyethers. Among these, novolak resin is particularly preferable as the polymer compound used for forming the dispersion phase.

(1) Examples of the structural unit include acrylamides, methacrylamides, acrylic esters and methacrylic esters having an aromatic hydroxyl group. Specific examples these compounds include N-(4-hydroxyphenyl)acrylamide or N-(4-hydroxyphenyl)methacrylamide, o-, p- or m-hydroxyphenyl acrylate or methacrylate and 2-hydroxyethylmethacrylate.

(2) Examples of the above structural unit also include unsaturated carboxylic acids such as acrylic acid, methacrylic acid, maleic anhydride and itaconic acid.

(3) Examples of the structural unit also include low-molecular weight compounds having at least one sulfonamide group having at least one hydrogen atom bonded to the nitrogen atom, and at least one polymerizable unsaturated bond, for example, compounds represented by the following Formulae (i) to (v).

Formulae (i) to (v),

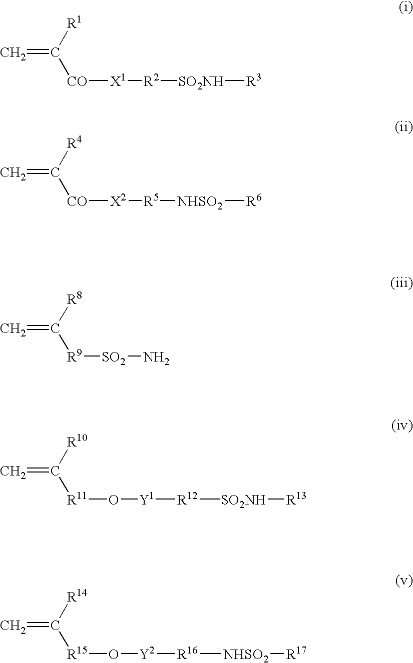

In Formulae (i) to (v), X¹ and X² each independently represent —O—, or —NR⁷—; R¹ and R⁴ each independently represent a hydrogen atom, or —CH₃; R², R⁵, R⁹, R¹² and R¹⁶ each independently represent an alkylene group, a cycloalkylene group, an arylene group or an aralkylene group which has 1 to 12 carbon atoms and may have a substituent; R³, R⁷ and R¹³ each independently represent a hydrogen atom, or an alkyl group, a cycloalkyl group, an aryl group or an aralkyl group which has 1 to 12 carbon atoms and may have a substituent; R⁶ and R¹⁷ each independently represent an alkyl group, a cycloalkyl group, an aryl group or an aralkyl group which has 1 to 12 carbon atoms and may have a substituent; R⁸, R¹⁰ and R¹⁴ each independently represent a hydrogen atom, a halogen atom or —CH₃; R¹¹ and R¹⁵ each independently represent a single bond, or an alkylene group, a cycloalkylene group, an arylene group or an aralkylene group which has 1 to 12 carbon atoms and may have a substituent; and Y¹ and Y² each independently represent a single bond or —CO—.

Specific examples of the compounds represented by any one of Formulae (i) to (v) include m-aminosulfonylphenyl methacrylate, N-(p-aminosulfonylphenyl)methacrylamide and N-(p-aminosulfonylphenyl)acrylamide.

(4) Examples of the structural unit also include low-molecular weight compounds containing at least one active imino group represented by the following Formula (vi) and at least one polymerizable unsaturated bond, for example, N-(p-toluenesulfonyl)methacrylimide and N-(p-toluenesulfonyl)acrylimide.

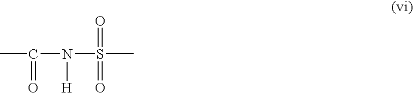

(5) Examples of the above structural unit also include styrene compounds, vinyl acetate and vinyl alcohol, for example, o-, m- or p-hydroxystyrene, styrene p-sulfonate and o-, m- or p-carboxylstyrene.

The monomers corresponding to any one of the above (1) to (5) may be used either singly or in combinations of two or more. Copolymers obtained by combining any one of these monomers (1) to (5) with monomers other than these monomers are more preferable. In this case, the structural unit derived from any one of the above monomers (1) to (5) is contained in an amount 10 mole % or more, preferably 20 mole % or more and still more preferably 25 mole % or more of such a copolymer. Examples of the monomer used in combination with any one of the monomers (1) to (5) include the following compounds (6) to (16):

(6) acrylates and methacrylates having an aliphatic hydroxyl group, for example, 2-hydroxyethylacrylate or 2-hydroxyethylmethacrylate;

(7) (substituted) alkylacrylates such as methylacrylate, ethylacrylate, propylacrylate, butylacrylate, amylacrylate, hexylacrylate, octylacrylate, benzylacrylate, 2-chloroethylacrylate, glycidylacrylate and N-dimethylaminoethylacrylate;

(8) (substituted) alkylmethacrylates such as methylmethacrylate, ethylmethacrylate, propylmethacrylate, butylmethacrylate, amylmethacrylate, hexylmethacrylate, cyclohexylmethacrylate, benzylmethacrylate, glycidylmethacrylate and N-dimethylaminoethylmethacrylate;

(9) acrylamides or methacrylic acid amides such as acrylamide, methacrylamide, N-methylolacrylamide, N-ethylacrylamide, N-hexylmethacrylamide, N-cyclohexylacrylamide, N-hydroxyethylacrylamide, N-phenylacrylamide, N-nitrophenylacrylamide and N-ethyl-N-phenylacrylamide;

(10) vinyl ethers such as ethyl vinyl ether, 2-chloroethyl vinyl ether, hydroxyethyl vinyl ether, propyl vinyl ether, butyl vinyl ether, octyl vinyl ether and phenyl vinyl ether;

(11) vinyl esters such as vinyl acetate, vinyl chloroacetate, vinyl butyrate and vinyl benzoate;

(12) styrenes such as styrene, α-methylstyrene, methylstyrene and chloromethylstyrene;

(13) vinyl ketones such as methyl vinyl ketone, ethyl vinyl ketone, propyl vinyl ketone and phenyl vinyl ketone;

(14) olefins such as ethylene, propylene, isobutylene, butadiene and isoprene;

(15) N-vinylpyrrolidone, N-vinylcarbazole, 4-vinylpyridine, acrylonitrile and methacrylonitrile; and

(16) unsaturated imides such as maleimide, N-acryloylacrylamide, N-acetylmethacrylamide, N-propionylmethacrylamide and N-(p-chlorobenzoyl)methacrylamide.

Furthermore, monomers copolymerizable with the above monomers may be copolymerized to form the polymer compound. The polymer compound preferably has a weight average molecular weight of 2,000 or more and a number average molecular weight of 1000 or more, and more preferably has a weight average molecular weight of 5,000 to 300,000, a number average molecular weight of 2,000 to 250,000 and a degree of dispersion (the weight average molecular weight/the number average molecular weight) of 1.1 to 10.

Examples of the water-insoluble and aqueous alkali solution-soluble urethane polymer compound which can be used in the invention include, though not limited to, urethane type polymer compounds described in each publication of JP-A Nos. 63-124047, 63-287946, 2-866 and 2-156241.

In the invention, the acryl polymer compound may be used together with the urethane polymer compound.

Examples of the alkali-soluble novolak resin used in the invention may include alkali-soluble novolak resins such as a phenolformaldehyde resin, xylenol cresolformaldehyde resin (3,5-, 2,3-, 2,4-, and 2,5-xylenols), m-cresolformaldehyde resin, p-cresolformaldehyde resin, m-/p-mixed cresolformaldehyde resin and phenol/cresol (any of m-, p- and m-/p-mixture) mixed formaldehyde resin. As these alkali-soluble novolak resins, those having a weight average molecular weight of 500 to 20,000 and a number average molecular weight of 200 to 10,000 are used. Further, a condensate of a phenol having an alkyl group having 3 to 8 carbon atoms as a substituent and formaldehyde such as a t-butylphenolformaldehyde resin and octylphenolformaldehyde resin as described in U.S. Pat. No. 4,123,279 may be used together.

The alkali-soluble novolak resin preferably has a high content of a novolak resin, the bonding property of an ortho position thereof being high. Examples of such novolak resin include a xylenol cresol formaldehyde resin, a m-cresol formaldehyde resin or a p-cresol formaldehyde resin. Any of those specific novolak resins are preferably contained in an amount of preferably 10 mass % or more, and more preferably 30 mass % or more relative to the total amount of the whole novolak resin used in the alkali-soluble novolak resin.

The lower recording layer having a polymer matrix phase containing the thus formed dispersion phase contains, in the dispersion phase, a compound which changes the solubility in an alkaline solution due to the action of the infrared absorber and heat in a high content in the case that the lower recording layer is a positive-working recording layer, thereby efficiently improves the solubility of the polymer matrix phase in an alkaline solution.

Next, compounds which can be contained in the dispersion phase will be explained, respectively.

The dispersion phase may contain an acid generator that is decomposed by the action of light or heat to generate an acid, to improve the solubility in aqueous alkali of the aqueous alkali-soluble polymer compound in an exposed area.

The “acid generator” means those that generate an acid by irradiation with light having a wavelength of 200 nm to 500 nm or by heating at 100° C. or more. Examples of the acid generator include known compound which is thermally decomposed to generate an acid such as a photoinitiator for photo-cationic polymerization, a photoinitiator for photo-radical polymerization, a photo-achromatizing agent for dyes, a photo-discoloring agent, known acid generators used for micro-resist, and mixtures of these compounds. The acid which is generated from the acid generator is preferably a strong acid having a pKa of 2 or less such as sulfonic acid and hydrochloric acid.

Preferable examples of the initiator include the triazine compounds described in JP-A No. 11-95415 and the latent Bronsted acid described in JP-A No. 7-20629. Here, the latent Bronsted acid means a precursor which generates a Bronsted acid by being decomposed. It is assumed that the Bronsted acid catalyzes a matrix generating reaction between a resol resin and a novolak resin. Typical examples of the Bronsted acid fitted to this purpose include trifluoromethanesulfonic acid and hexafluorophosphonic acid.

An ionic latent Bronsted acid may be preferably used in the invention. Examples of the ionic latent Bronsted acid include onium salts, particularly, iodonium, sulfonium, phosphonium, selenonium, diazonium and arsonium salts. Particularly useful and specific examples of the onium salt include diphenyliodonium hexafluorophosphate, triphenylsulfonium hexafluoroantimonate, phenylmethyl-ortho-cyanobenzylsulfonium trifluoromethane sulfonate and 2-methoxy-4-aminophenyldiazonium hexafluorophosphate.

Nonionic latent Bronsted acids are also appropriately used in the invention. Examples of these nonionic latent Bronsted acids include compounds represented by the following formula:

RCH₂X, RCHX₂, RCX₃, R(CH₂X)₂ and R(CH₂X)₃ (wherein X represents Cl, Br, F or CF₃SO₃ and R represents an aromatic group, an aliphatic group or a combination of an aromatic group and an aliphatic group).

Useful ionic latent Bronsted acids are those represented by the following formula.

X⁺R¹R²R³R⁴W⁻

In the formula, when X is iodine, R³ and R⁴ respectively represent a lone electron pair and R¹ and R² respectively represent an aryl or substituted aryl group. When X is S or Se, R⁴ represents a lone electron pair and R¹, R² and R³ respectively may represent an aryl group, a substituted aryl group, an aliphatic group or substituted aliphatic group. When X is P or As, R⁴ may represent an aryl group, a substituted aryl group, an aliphatic group or a substituted aliphatic group. W represents BF₄, CF₃SO₃, SbF₆, CCl₃CO₂, ClO₄, AsF₆, PF₆ or may be any corresponding acid having a pH value of less than 3. All the onium salts described in U.S. Pat. No. 4,708,925 may be used as the latent Bronsted acid used in the invention. Examples of these onium salts include indonium, sulfonium, phosphonium, bromonium, chloronium, oxysulfoxonium, oxysulfonium, sulfoxonium, selenonium, telluronium and arsonium.

It is particularly preferable to use a diazonium salt as the latent Bronsted acid. These diazonium salts provide a sensitivity equivalent to that of other latent Bronsted acids in the infrared region and a higher sensitivity than that of the other latent Bronsted acids in the ultraviolet region.

The acid generator can be added in the proportion of 0.01 to 50 mass %, preferably 0. 1 to 25 mass % and more preferably 0.5 to 20 mass % with respect to the total solid content of the lower recording layer from the viewpoint of image formability and from the viewpoint of preventing scumming in a non-image area.

Not only the components described above but also a wide variety of known additives can be used in combination in the positive-working recording layer of the planographic printing plate precursor of the invention in accordance with the intended use. Among plural recording layers, the lower recording layer is required to form the dispersion phase therein. Regarding other additives, the same additives may be used in both the lower recording layer and the other recording layers.

A fluorine-containing polymer is preferably added to each recording layer of the invention for the purpose of improving the resistance to development in an image area. Examples of the fluorine-containing polymer used in the image recording layer include copolymers formed from fluorine-containing monomers as described in JP-A Nos. 11-288093 and 2000-187318.

Preferable and specific examples of the fluorine-containing polymer include fluorine-containing acryl polymers P-1 to P-13 as described in JP-A No. 11-288093 and fluorine-containing polymers obtained by copolymerizing fluorine-containing acryl monomers A-1 to A-33 as described in JP-A No. 2000-187318 with arbitrary acryl monomers.

The fluorine-containing polymer exemplified above preferably has a weight average molecular weight of 2,000 or more and a number average molecular weight of 1,000 or more. It is more preferable that the weight average molecular weight is 5,000 to 300,000 and the number average molecular weight is 2,000 to 250,000.

Commercially available fluorine surfactants having the preferable molecular weight may be used as the fluorine-containing polymer. Specific examples of such surfactants include MEGAFACE F-171, F-173, F-176, F-183, F-184, F-780 and F-781 (all are trade names, manufactured by DIC Corporation).

These fluorine-containing polymers may be used either singly or combinations of two or more.

It is necessary that the amount of the fluorine-containing polymer is 1.4 mass % or more based on the solid content of the image recording layer to meet the requirements in the invention. The amount is preferably 1.4 to 5.0 mass %. When the amount is below 1.4 mass %, the purpose of the addition of the fluorine-containing polymer, namely, the effect of improving the development latitude of the image recording layer may become insufficient. Even if the fluorine-containing polymer is added in an amount exceeding 5.0 mass %, the effect of improving the development latitude cannot be fully exerted, but, there is a fear that the solubility of the surface of the image recording layer may become more sparing under the influence of the fluorine-containing polymer, resulting in a decrease in sensitivity.

A dissolution inhibitor, which is a thermally decomposable material and substantially lowers the solubility of the aqueous alkali-soluble polymer compound in the undecomposed state, may be additionally used in the lower recording layer or other layers of the precursor of the invention as needed. Examples of the dissolution inhibitor include an onium salt, an o-quinonediazide compound, an aromatic sulfone compound and an aromatic sulfonate compound. The addition of the dissolution inhibitor makes it possible not only to improve the resistance to dissolution of the image area in a developer but also to use, as an infrared absorber, a compound which does not interact with the alkali-soluble polymer. Examples of the onium salt include diazonium salts, ammonium salts, phosphonium salts, iodonium salts, sulfonium salts, selenonium salts and arsonium salts.

Preferable examples of the onium salt used in the invention include diazonium salts described in S. I. Schlesinger, Photogr. Sci. Eng., 18, 387 (1974), T. S. Bal et al., Polymer, 21, 423 (1980), and JP-A No. 5-158230; ammonium salts described in U.S. Pat. Nos. 4,069,055 and 4,069,056, and JP-A No. 3-140140; phosphonium salts described in D. C. Necker et al., Macromolecules, 17, 2468 (1984), C. S. Wen et al., Teh, Proc. Conf. Rad. Curing ASIA, pp 478 Tokyo, October (1988), and U.S. Pat. Nos. 4,069,055 and 4,069,056; iodonium salts described in J. V. Crivello et al., Macromolecules, 10 (6), 1307 (1977), Chem. & Eng. News, November 28, pp 31 (1988), EP No. 104,143, U.S. Pat. Nos. 5,041,358 and 4,491,628, and JP-A Nos. 2-150848 and 2-296514;

sulfonium salts described in J. V. Crivello et al., Polymer J. 17, 73 (1985), J. V. Crivello et al., J. Org. Chem., 43, 3055 (1978), W. R. Watt et al., J. Polymer Sci., Polymer Chem. Ed., 22, 1789 (1984), J. V. Crivello et al., Polymer Bull., 14, 279 (1985), J. V. Crivello et al., Macromolecules, 14 (5), 1141 (1981), J. V. Crivello et al., J. Polymer Sci., Polymer Chem. Ed., 17, 2877 (1979), EP Nos. 370,693, 233,567, 297,443 and 297,442, U.S. Pat. Nos. 4,933,377, 3,902,114, 4,491,628, 5,041,358, 4,760,013, 4,734,444 and 2,833,827, and DE Pat. Nos. 2,904,626, 3,604,580 and 3,604,581; selenonium salts described in J. V. Crivello et al., Macromolecules, 10 (6), 1307 (1977), J. V. Crivello et al., J. Polymer Sci., Polymer Chem. Ed., 17, 1047 (1979); and arsonium salts described in C. S. Wen et al., and The Proc. Conf. Rad. Curing ASIA, pp 478, Tokyo, October (1988).

A diazonium salt is particularly preferably used as the dissolution inhibitor. Particularly preferable examples of the diazonium salt include those described in JP-A No. 5-158230.

Examples of the counter ion of the onium salt include tetrafluoroboric acid, hexafluorophosphoric acid, triisopropylnaphthalenesulfonic acid, 5-nitro-o-toluenesulfonic acid, 5-sulfosalicylic acid, 2,5-dimethylbenzenesulfonic acid, 2,4,6-trimethylbenzenesulfonic acid, 2-nitrobenzenesulfonic acid, 3-chlorobenzenesulfonic acid, 3-bromobenzenesulfonic acid, 2-fluorocaprylnaphthalenesulfonic acid, dodecylbenzenesulfonic acid, 1-naphthol-5-sulfonic acid, 2-methoxy-4-hydroxy-5-benzoyl-benzenesulfonic acid, and p-toluenesulfonic acid. Among these examples, hexafluorophosphoric acid, and alkylaromatic sulfonic acids such as triisopropylnaphthalenesulfonic acid and 2,5-dimethylbezenesulfonic acid are particularly preferable.

Preferable examples of the quinonediazide include an o-quinonediazide compound. The o-quinonediazide compounds used in the invention are compounds which have at least one o-quinonediazide group and increase the alkali-solubility by being thermally decomposed, and compounds having various structures may be used. In other words, the o-quinonediazide compound enhances the solubility of the photosensitive system by the both effects that the effects of losing the function of suppressing the dissolution of the binder due to the thermal decomposion of the o-quinonediazide as well as the effect of changing the o-quinonediazide itself to an alkali-soluble material.

Preferable examples of the o-quinonediazide compound used in the invention include compounds described in J. Koser, “Light—Sensitive Systems” (John Wiley & Sons. Inc.), pp. 339-352. Particularly preferable are sulfonic acid esters or sulfonamides of o-quinonediazide formed by allowing to react with various aromatic polyhydroxy compounds or with aromatic amino compounds. Preferable examples of the o-quinonediazide compound further include an ester of benzoquinone-(1,2)-diazidesulfonic acid chloride or naphthoquinone-(1,2)-diazide-5-sulfonic acid chloride and a pyrogallol-acetone resin, as described in JP-B No. 43-28403; and an ester of benzoquinone-(1,2)-diazidesulfonic acid chloride or naphthoquinone-(1,2)-diazide-5-sulfonic acid chloride and a phenol-formaldehyde resin.

Preferable examples of the o-quinonediazide compound further include an ester of naphthoquinone-(1,2)-diazide-4-sulfonic acid chloride and a phenol-formaldehyde resin or cresol-formaldehyde resin; and an ester of naphthoquinone-(1,2)-diazide-4-sulfonic acid chloride and a pyrogallol-acetone resin. Other useful o-quinonediazide compounds are reported in unexamined or examined patent documents, examples of which include JP-A Nos. 47-5303, 48-63802, 48-63803, 48-96575, 49-38701 and 48-13354, JP-B Nos. 41-11222, 45-9610 and 49-17481, U.S. Pat. Nos. 2,797,213, 3,454,400, 3,544,323, 3,573,917, 3,674,495 and 3,785,825, GB Patent Nos. 1,227,602, 1,251,345, 1,267,005, 1,329,888 and 1,330,932, and DE Pat. No. 854,890.

The addition amount of the o-quinonediazide compound is preferably in the range from 1 mass % to 50 mass %, more preferably in a range from 5 mass % to 30 mass %, and particularly preferably in a range from 10 mass % to 30 mass % with respect to the total solid content of each recording layer. These compounds may be used singly or as a mixture of plural kinds thereof.

The addition amount of the additives other than the o-quinonediazide compound is preferably 1 mass % to 50 mass %, more preferably 5 mass % to 30 mass %, and particularly preferably 10 mass % to 30 mass %. The additives and binder used in the invention are preferably contained in the same layer.

A polymer containing a (meth)acrylate monomer having two or three perfluoroalkyl group having 3 to 20 carbon atoms in the molecule as a polymerization component, as described in the specification of JP-A No. 2000-87318 may be used together for the purpose of intensifying the discrimination of an image to be formed and enhancing resistance to blemish on the surface of the precursor of the invention.

In order to increase the sensitivity, the recording layer may further contain a cyclic acid anhydride, a phenolic compound, an organic acid or the like.

Examples of the cyclic acid anhydride include phthalic anhydride, tetrahydrophthalic anhydride, hexahydrophthalic anhydride, 3,6-endooxy-Δ4-tetrahydrophthalic anhydride, tetrachlorophthalic anhydride, maleic anhydride, chloromaleic anhydride, α-phenylmaleic anhydride, succinic anhydride and pyromellitic anhydride, as described in U.S. Pat. No. 4,115,128.

Examples of the phenolic compound include bisphenol A, p-nitrophenol, p-ethoxyphenol, 2,4,4′-trihydroxybenzophenone, 2,3,4-trihydroxybenzophenone, 4-hydroxybenzophenone, 4,4′,4″-trihydroxytriphenylmethane and 4,4′,3″,4″-tetrahydroxy-3,5,3′,5′-tetramethyltriphenylmethane.

Examples of the organic acid include sulfonic acids, sulfinic acids, alkylsulfuric acids, phosphonic acids, phosphates, and carboxylic acids, as described in JP-A Nos. 60-88942 and 2-96755. Specific examples thereof include p-toluenesulfonic acid, dodecylbenzenesulfonic acid, p-toluenesulfinic acid, ethylsulfuric acid, phenylphosphonic acid, phenylphosphinic acid, phenyl phosphate, diphenyl phosphate, benzoic acid, isophthalic acid, adipic acid, p-toluic acid, 3,4-dimethoxybenzoic acid, phthalic acid, terephthalic acid, 4-cyclohexene-1,2-dicarboxylic acid, erucic acid, lauric acid, n-undecanoic acid and ascorbic acid.

The content of the cyclic acid anhydrides, the phenols or the organic acids in the recording layer of the planographic printing plate precursor is preferably from 0.05 to 20 mass %, more preferably from 0. 1 to 15 mass %, and particularly preferably from 0. 1 to 10 mass % with respect to the total solid content of the recording layer.

A dye having a large absorption in the visible light region may be added to each recording layer according to the invention as a colorant for an image. Examples of the dye include Oil Yellow #101, Oil Yellow #103, Oil Pink #312, Oil Green BG, Oil Blue BOS, Oil Blue #603, Oil Black BY, Oil Black BS and Oil Black T-505 (these products are manufactured by Orient Chemical Industries, Ltd.), Victoria Pure Blue, Crystal Violet (CI42555), Methyl Violet (CI42535), Ethyl Violet, Rhodamine B (CI145170B), Malachite Green (CI42000), Methylene Blue (CI52015), AIZEN SPILON BLUE C-RH (manufactured by Hodogaya Chemical Co., Ltd.), and dyes as described in JP-A No. 62-293247.

It is preferable that the distinction between an image area and a non-image area is clarified by the addition of these dyes after an image is formed. The amount of these dyes to be added is preferably in the range from 0.01 to 10 mass % relative to the total solid content of the recording layer.

In order to broaden the latitude of the processing stability in development, nonionic surfactants as described in JP-A Nos. 62-251740 and 3-208514, amphoteric surfactants as described in JP-A Nos. 59-121044 and 4-13149, siloxane compounds as described in EP No. 950517, or copolymers of fluorine-containing monomers as described in JP-A No. 11-288093 may be added to the image recording layer of the invention.

Specific examples of nooninic surfactants include sorbitan tristearate, sorbitan monopalmitate, sorbitan trioleate, stearyl monoglyceride and polyoxyethylene nonyl phenyl ether. Specific examples of amphoteric surfactants include alkyldi(aminoethyl)glycine, alkylpolyaminoethylglycine hydrochloride, 2-alkyl-N-carboxyethyl-N-hydroxyethylimidazolinium betaine and N-tetradecyl-N,N-betaine type surfactants (for example, “AMOGEN K” (trade name), manufactured by Dai-ichi Kogyo Seiyaku Co., Ltd.). The siloxane compounds are preferably block copolymers of dimethylsiloxane and polyalkylene oxide. Specific examples thereof include polyalkylene oxide modified silicones such as DBE-224, DBE-621, DBE-712, DBP-732 and DBP-534 (all trade names: manufactured by Chisso Corporation) or TEGO GLIDE 100 (trade name, manufactured by Evonik Tego Chemie GmbH, Germany).

The content of the nonionic surfactant and the amphoteric surfactant is preferably from 0.05 mass % to 15 mass %, and more preferably from 0.1 mass % to 5 mass % with respect to the total solid content of the recording layer.

A printing-out agent, which is a material for obtaining a visible image immediately after the photosensitive composition of the invention has been heated by exposure to light, or a dye or pigment as a colorant for an image, may be added to the planographic printing plate precursor of the invention. A typical example of the printing-out agent is a combination of an organic dye which can form a salt with a compound which can release an acid due to heating upon exposure to light (photo-acid releasing agent).

Specific examples the combination include combinations of an o-naphthoquinonediazide-4-sulfonic acid halogenide with a salt-formable organic dye, as described in JP-A Nos. 50-36209 and 53-8128; and combinations of a trihalomethyl compound with a salt-formable organic dye, as described in each of JP-A Nos. 53-36223, 54-74728, 60-3626, 61-143748, 61-151644 and 63-58440. The trihalomethyl compound is classified into an oxazol compound or a triazine compound. Both of the compounds have an excellent temporal stability and produce a clear print-out image. Examples of the photo-acid releasing agent further include various o-naphthoquinonediazide compounds as described in JP-A No. 55-62444, 2-trihalomethyl-5-aryl-1,3,4-oxadiazole compound as described in JP-A No. 55-77742, and diazonium salts.

A plasticizer may be optionally added to a coating liquid for forming the recording layer of the invention to give flexibility to a coated layer. Examples of the plasticizer include butyl phthalyl, polyethylene glycol, tributyl citrate, diethyl phthalate, dibutyl phthalate, dihexyl phthalate, dioctyl phthalate, tricresyl phosphate, tributyl phosphate, trioctyl phosphate, tetrahydrofurfuryl oleate, oligomers and polymers of acrylic acid or methacrylic acid.

The planographic printing plate precursor of the invention may be usually produced by sequentially coating, coating liquids, in which the components are dissolved in a solvent, for forming respective recording layers onto an appropriate support.

Examples of the solvent suitable for coating the coating liquid for the recording layer include, though not limited to, ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylacetamide, N,N-dimethylformamide, tetramethylurea, N-methylpyrrolidone, dimethylsulfoxide, sulfolane, γ-butyrolactone and toluene. These solvents may be used either singly or as a mixture of two or more of them. The concentration of the above components (total solid content including additives) in the solvent is preferably 1 mass % to 50 mass %.

It is preferable that a lower recording layer and an upper recording layer (other recording layers) on the lower recording layer are separately formed from each other in principle.

Examples of the method of forming separately the two layers from each other include a method of utilizing a difference between the solubility of the components contained in the lower recording layer in a solvent and that of the components contained in the upper layer, and a method in which a solvent is vaporized and removed quickly by drying after the upper layer is applied, but the methods are not limited thereto.

Examples of the method of utilizing the difference between the solubility of the components contained in the lower recording layer in a solvent and that of the components contained in the upper layer include a method which uses a solvent which does not dissolve the alkali-soluble polymer contained in the lower recording layer when the coating liquid for the upper layer is coated. In this way, even if two-layers are coated, it is possible to separate the layers from each other clearly to form coated layers. For example, a component insoluble in a solvent such as methyl ethyl ketone and 1-methoxy-2-propanol, which dissolve the alkali-soluble polymer which is a component in the upper layer, is selected as the component of the lower recording layer, the lower recording layer is coated by using the solvent which dissolves a component contained in the lower recording layer, and the coated layer is dried, thereafter, a component containing the alkali-soluble polymer as a primary component for the upper recording layer is dissolved in methyl ethyl ketone, 1-methoxy-2-propanol or the like, and the upper layer coating liquid is coated and dried, thereby the formation of two layers can be attained.

When a method of using a solvent which does not dissolve the alkali-soluble polymer contained in the lower recording layer is used when the upper layer coating liquid is coated, a solvent which dissolves the alkali-soluble polymer contained in the lower recording layer may be mixed with a solvent which doe not dissolve this alkali-soluble polymer. The interlayer mixing between the upper layer and the lower recording layer can be arbitrarily controlled by changing the mixing ratio of the both solvents. If the proportion of the solvent that dissolves the alkali-soluble polymer contained in the lower recording layer is increased, a part of the lower recording layer is dissolved when applying the upper layer and the dissolved component becomes to be contained in the upper layer as particle-shape components after being dried. The particle-shape components form projections on the surface of the upper layer, thereby improving resistance to blemish. On the other hand, the components in the lower recording layer are eluted into the upper recording layer, resulting in a tendency of deterioration of the layer quality of the lower recording layer, and decrease in resistance to chemicals of the lower recording layer. Thus, by controlling of the mixing ratio in consideration of physical properties for each layer, various characteristics can be exhibited, and further, partial compatibility between the layers can be developed, which will be described hereinafter.

When a mixed solvent as mentioned above is used as a solvent for the coating liquid of the upper layer in view of the effect of the invention, the amount of a solvent which can dissolve the alkali-soluble polymer in the lower recording layer is preferably 80 mass % or less relative to the amount of the solvent used to the coating liquid of the upper layer from the viewpoint of resistance to chemicals, and more preferably in the range from 10 mass % to 60 mass %, by further taking into account the resistance to blemish.

Examples of the method of drying a solvent very quickly after the second layer (upper recording layer) is coated include a method of blowing a high pressure air from a slit nozzle arranged approximately perpendicular to the moving direction of a web, a method of supplying thermal energy as conductive heat to a web from the underside of the web through a roll (heating roll), into which a heating medium such as steam is supplied, and the combination of these methods.

Various methods may be used as a method of coating each of the layers such as the image recording layer. Examples of the coating method may include a bar coater coating, a rotary coating, a spray coating, a curtain coating, a dip coating, an air knife coating, a blade coating and a roll coating.

The coating method used to form the upper recording layer is preferably carried out in a non-contact system to prevent damages to the lower recording layer when coating the upper recording layer. While a bar coater coating, though it is a contact system, may be used as the method generally used in a solvent system coating, it is desirable to carry out the coating in a forward rotation drive to prevent damages to the lower recording layer.

The coating amount of the recording layer after the layer is dried in the planographic printing plate precursor of the invention is preferably in the range of from 0.7 g/m² to 4.0 g/m² and more preferably in the range of from 0.8 g/m² to 3.0 g/m² in the case of a single layer, from the viewpoint of ensuring printing durability and suppressing generation of layer residues during development.

Further, in the case of a multiple layer structure, the coating amount of the lower recording layer after being dried is preferably in the range of from 0.5 g/m² to 1.5 g/m², and more preferably in the range of from 0.7 g/m² to 1.0 g/m², from the viewpoint of ensuring printing durability and suppressing generation of layer residues during development , and the coating amount of the upper recording layer after being dried is preferably in the range of from 0.05 g/m² to 1.0 g/m², and more preferably in the range of from 0.07 g/m² to 0.7 g/m². When the upper recording layer is formed by two or more layers, the coating amount is the total coating amount thereof.

A surfactant such as a fluorine-based surfactant as described in JP-A No. 62-170950 may be added to the coating liquid for the recording layer in the invention to improve coating characteristics. The amount of the surfactant is preferably 0.01 mass % to 1 mass % and more preferably 0.05 mass % to 0.5 mass % relative to the total solid content of the coating liquid.

[Hydrophilic support having surface roughness (Ra) from 0.45 to 0.60]

The support used for the invention is not specifically restricted as far as the support is a hydrophilic support which is dimensionally stable tabular, and has a surface roughness of from 0.45 to 0.60.

Examples of the support substrates include paper, paper laminated with plastics (for example, polyethylene, polypropylene, polystyrene and the like), metal plates (for example, aluminum, zinc, copper and the like), plastic film (for example, cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate, polyvinyl acetal and the like), and paper or plastic film laminated or deposited with the metal in the above.

As the support usable in the invention, from the viewpoint of achieving the surface roughness, a polyester film or an aluminum plate is preferable, and in particular, the aluminum plate is preferable in view of a good dimension stability and relatively low cost.

Preferable examples of the aluminum plate include a pure aluminum plate and alloy plates made of aluminum as a main component containing trace amounts of other elements. A plastic film on which aluminum is laminated or vapor-deposited may also be used. Examples of other elements which may be contained in the aluminum alloys include silicon, iron, manganese, copper, magnesium, chromium, zinc, bismuth, nickel, and titanium. The content by percentage of foreign elements in the alloy is at most 10 mass %. A particularly preferable aluminum plate in the invention is a pure aluminum plate, however, since a completely pure aluminum cannot be easily produced, trace amounts of other elements may also be contained in the plate, from the viewpoint of refining techniques.

The aluminum plate used as the support is not specified in terms of the composition thereof. Thus, aluminum plates which are conventionally known can be appropriately used. The thickness of the aluminum plate used in the invention is from about 0. 1 mm to 0.6 mm, preferably from 0.15 mm to 0.4 mm, and more preferably from 0.2 mm to 0.3 mm.

If necessary, the aluminum plate may be arbitrarily subjected to a degreasing treatment prior to the surface-roughening treatment, in order to remove rolling oil or the like on the surface, with the use of a surfactant, an organic solvent, an aqueous alkaline solution or the like.

The surface-roughening treatment of the aluminum surface can be performed by various methods such as a mechanical surface-roughening method, a method of dissolving and roughening the surface electrochemically, or a method of dissolving the surface selectively in a chemical manner.

Mechanical surface-roughening methods which can be used may be known methods, such as a ball polishing method, a brush polishing method, a blast polishing method or a buff polishing method. An electrochemical surface-roughening method may be a method of performing surface-roughening in an electrolyte of hydrochloric acid or nitric acid, by use of an alternating current or a direct current. As disclosed in JP-A No. 54-63902, a combination of the two kinds of methods may be used.

An aluminum plate whose surface is roughened as described above is optionally subjected to an alkali-etching treatment and a neutralizing treatment. Thereafter, an anodizing treatment is applied in order to improve the water holding capacity and wear resistance of the surface, if necessary.

The electrolyte used in the anodizing treatment of the aluminum plate is any one selected from various electrolytes which can form a porous anodized layer. In general, electrolytes such as sulfuric acid, phosphoric acid, oxalic acid and chromic acid, or a mixed acid thereof may be used. The concentration of the electrolyte may be appropriately decided depending on the kind of the electrolyte selected.

The condition of roughening the surface is appropriately adjusted, and an aluminum support having the following surface roughness can be prepared.

It is required that the support of the invention has a surface roughness (Ra) of from 0.45 to 0.60 (μm). When the surface roughness (arithmetic average surface roughness Ra) of the hydrophilic support is less than 0.45 μm, there is a fear of an increase in side etching and reduction in resolution, and when the surface roughness Ra is larger than 0.60 μm, there is a tendency of reduction in the developability, and both are undesirable.

In the invention, the surface roughness is measured in accordance with the methods stipulated in JIS B 0601-1994, and more specifically is measured by the use of a stylus meter.

In order to form a hydrophilic support having such a surface roughness, the condition of roughening the surface of the support is important. As a suitable method of attaining the surface configuration with Ra, an electrochemical surface treatment using a hydrochloric acid electrolytic process is exemplified.

### Electrochemical Surface Roughening Treatment in Electrolytic Solution Containing Hydrochloric Acid as Main Component

The concentration of hydrochloric acid in an electrolytic solution used for the electrochemical surface roughening treatment to obtain the hydrophilic support of the invention is preferably from 5.0 g/L to 20.0 g/L, and more preferably from 10.0 g/L to 18 g/L.

Further, the concentration of aluminum ion in the electrolytic solution is from 5.0 g/L to 20.0 g/L, and preferably from 10.0 g/L to 18.0 g/L. The concentration of the aluminum ion, for example, can be controlled by adding aluminum chloride.

Furthermore, an electrolytic solution prepared by adding 1-10 g/L of sulfuric acid in the aqueous solution containing mainly hydrochloric acid is used for surface roughening electrochemically by applying an alternating current. The addition of sulfuric acid enables the formation of crater-shaped pits more uniformly.

In the electrolytic solution used here, at least one of chlorine compounds containing chlorine ion such as aluminum chloride, sodium chloride and ammonium chloride is added and used in the range of from 1 g/L to the saturated concentration. Further, metals contained in an aluminum alloy such as iron, copper, manganese, nickel, titanium, magnesium and silica may be contained in the electrolytic solution.

The temperature of the electrolytic solution is preferably from 25° C. to 45° C., and more preferably from 30° C. to 40° C.

The waveform of the alternating current used for the electrolytic surface roughening treatment is not specifically limited, but a sine wave, rectangular wave, a trapezoid wave and triangular wave may be used, and in particular, a sine wave is preferable. The current waveform applied to the aluminum plate is symmetrical on the positive and negative sides.

The current density in the electrolytic surface roughening treatment is preferably from 10 A/dm² to 400 A/dm², more preferably from 15 A/dm² to 350 A/dm² and still more preferably from 20 A/dm²to 300 A/dm² at the peak current value in the alternating current waveform.

The frequency of the alternating current usable in the electrochemical surface roughening treatment is preferably from 0.1 Hz to 120 Hz, and more preferably from 40 Hz to 70 Hz.

As an electrolytic bath, known electrolytic baths used for known surface treatments in which a plurality of electrodes are provided in an electrolytic bath such as known vertical type, flat type and radial type electrolytic baths may be used. The electrolytic solution passing though the electrolytic bath may be either a parallel flow or a counter flow with respect to the moving direction of the aluminum web. One to ten of electrolytic baths are preferably arranged in series in the moving direction of the aluminum plate, and in particular, two to six baths are preferably used. An arbitrary point on the moving aluminum plate is set a reference point, the interval between the plural electrodes provided in the electrolytic bath is preferably 0.001 to 0.5 second, and the interval between plural electrolytic baths is preferably 1 to 10 seconds. The quantity of electricity applied to an aluminum plate per one electrode is preferably 1 to 10 C/dm². When plural electrolytic baths are used, the quantity of electricity applied to one electrolytic bath is preferably 80 to 200 C/dm².

As a method of applying the electric current is preferably a method in which the current density is set to be lower at the inlet of the electrolytic bath as described in JP-A No. 10-280199 and EP 1033420 B1. By the use of this method, a rough surface with a uniform surface configuration, and less occurrence of treatment unevenness can be obtained.

The quantity of electricity of the invention is preferably 50 to 800 C/dm², and more preferably 300 to 600 C/dm² as a sum of the quantity of electricity associated with the anodic reaction of the aluminum plate.

By such a surface roughening treatment, the aluminum support with the specific surface roughness is subjected to an anodic oxidation treatment, and further optionally a hydrophilicizing treatment, so that a hydrophilic support usable in the invention with a surface roughness (Ra) of 0.45 to 0.60 can be obtained.

### Anodic Oxidation Treatment

Treatment conditions for anodic oxidation cannot be specified in general, since conditions may vary depending on the electrolyte used, however, it is generally preferable that the concentration of electrolyte is from 1 mass % to 80 mass %, the solution temperature is from 5° C. to 70° C., the current density is from 5 A/dm² to 60 A/dm², the voltage is from 1 V to 100 V, and the electrolyzing time is from 10 seconds to 5 minutes. If the amount of anodized layer is less than 1.0 g/m², printing durability is insufficient or non-image areas of the planographic printing plate tend to be easily blemished, and a so-called “blemish stain”, resulting from ink adhering to blemished portions at the time of printing, is easily generated.

Hydrophilicizing Treatment

After the anodizing treatment, the surface of the aluminum is subjected to a hydrophilicizing treatment, if necessary. Examples of the hydrophilicizing treatment include a method using an alkali metal silicate (for example, an aqueous sodium silicate solution) as disclosed in U.S. Pat. Nos. 2,714,066, 3,181,461, 3,280,734 and 3,902,734. In this method, the support is subjected to an immersing treatment or an electrolytic treatment with an aqueous sodium silicate solution.

In addition, a method of treating the support with potassium fluorozirconate as disclosed in JP-B No. 36-22063, or a method of treating the support with polyvinyl phosphonic acid as disclosed in U.S. Pat. Nos. 3,276,868, 4,153,461 and 4,689,272 may also be used.

The planographic printing plate precursor of the invention is formed by the recording layer on a support, but an undercoat layer may be optionally provided between the support and the recording layer.

Undercoat Layer

Various organic compounds can be used as components of the undercoat layer. Examples thereof include carboxymethylcellulose, dextrin, gum arabic, phosphonic acids having an amino group such as 2-aminoethylphosphonic acid, organic phosphonic acids which may have a substituent, such as phenyl phosphonic acid, naphthylphosphonic acid, alkylphosphonic acid, glycerophosphonic acid, methylenediphosphonic acid and ethylenediphosphonic acid, organic phosphoric acids which may have a substituent, such as phenylphosphoric acid, naphthylphosphoric acid, alkylphosphoric acid and glycerophosphoric acid, organic phosphinic acids which may have a substituent, such as phenylphosphinic acid, naphthylphosphinic acid, alkylphosphinic acid and glycerophosphinic acid, amino acids such as glycine and β-alanine, and hydrochlorides of amines having a hydroxyl group, such as a hydrochloride of triethanolamine. These organic compounds may be used alone or in the form of a mixture of two or more thereof.

Examples of the method for forming the organic undercoat layer include: a method of applying, onto the aluminum plate, a solution in which the above organic compound is dissolved in water, or an organic solvent such as methanol, ethanol or methyl ethyl ketone, or a mixed solvent thereof and then drying the resultant aluminum plate; and a method of immersing the aluminum plate into a solution in which the above organic compound is dissolved in water or an organic solvent such as methanol, ethanol, methyl ethyl ketone or a mixed solvent thereof so as to adsorb the compound, washing the aluminum plate with water or the like, and then drying the resultant aluminum plate. In the former method, the solution of the organic compound having a concentration of 0.005 to 10 mass % may be applied in various ways. In the latter method, the concentration of the organic compound in the solution is from 0.01 to 20 mass %, preferably from 0.05 to 5 mass %, the temperature for the immersion is from 20 to 90° C., preferably from 25 to 50° C., and the time for immersion is from 0.1 second to 20 minutes, preferably from 2 seconds to 1 minute.

The pH of the solution used in the above methods can be adjusted to a range of 1 to 12 with a basic material such as ammonia, triethylamine or potassium hydroxide, or an acidic material such as hydrochloric acid or phosphoric acid. Moreover, a yellow dye may be added to the solution, in order to improve the tone reproducibility of the image recording material.

The amount of the organic undercoat layer applied is suitably from 2 mg/m² to 200 mg/m², and is preferably from 5 mg/m² to 100 mg/m² from the viewpoint of printing durability.

The positive-working planographic printing plate precursor produced as described above is usually subjected to an imagewise exposure and developing process.

In the invention, the planographic printing plate precursor is exposed to light from a light source which preferably has an emitting wavelength in the near-infrared region to the infrared region. Specifically, the planographic printing plate precursor is preferably exposed imagewise to light from a solid laser or a semiconductor laser radiating infrared rays having a wavelength of 760 nm to 1,200 nm.

The planographic printing plate precursor of the invention is developed using water or an alkali developer after exposure. Although the developing process may be carried out immediately after exposure, a heat treatment may be carried out between an exposure step and a developing step. When the heat treatment is carried out, the heating is preferably carried out at a temperature range from 60° C. to 150° C. for 5 seconds to 5 minutes. As the heating method, conventionally known various methods may be used. Examples of the heating method include a method in which a recording material is heated with being in contact with a panel heater or ceramic heater, and a non-contact method using a lamp or hot air. This heat treatment enables the energy required for recording to be reduced at the time when the laser is irradiated.

Any conventionally known aqueous alkali solution may be used as a developer and replenisher to be used for plate-making of the planographic printing plate of the invention.

The developer which may be applied to the developing process of the planographic printing plate precursor of the invention is a developer having a pH range from 9.0 to 14.0 and preferably a pH range from 12.0 to 13.5. A conventionally known aqueous alkali solution may be used as the developer (hereinafter referred to as a developer including a replenisher).

Examples of the alkali agent for the aqueous alkali solution include inorganic alkali salts such as sodium silicate, potassium silicate, trisodium phosphate, tripotassium phosphate, triammonium phosphate, disodium hydrogenphosphate, dipotassium hydrogenphosphate, diammonium hydrogenphosphate, sodium carbonate, potassium carbonate, ammonium carbonate, sodium hydrogencarbonate, potassium hydrogencarbonate, ammonium hydrogen carbonate, sodium borate, potassium borate, ammonium borate, sodium hydroxide, ammonium hydroxide, potassium hydroxide or lithium hydroxide; and organic alkali agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, or pyridine.

These alkali agents may be used alone or in combinations of two or more thereof.

Moreover, an aqueous alkali solution containing a non-reducing sugar and a base may also be used. The non-reducing sugar refers to a sugar having no reducing ability due to lack of a free aldehyde group, a ketone group and the like, and is classified into trehalose oligosaccharides in which reducing groups are combined with one another, glycosides in which reducing groups of sugars are combined with non-sugars, and sugar alcohols in which sugars are reduced by hydrogenation. Any of these non-reducing sugars may be preferably used.

Examples of the trehalose oligosaccharides include saccharose and trehalose. Examples of the glucosides include alkylglucosides, phenolglucosides, and mustard seed oil glucoside. Examples of the sugar alcohols include D, L-arabitol, ribitol, xylitol, D, L-sorbitol, D, L-mannitol, D, L-iditol, D, L-talitol, dulcitol, and allodulcitol. Furthermore, maltitol obtained by hydrogenating a disaccharide, and a reductant obtained by hydrogenating an oligosaccharide (i.e., reduced starch syrup) are preferable. Of these examples, sugar alcohol and saccharose are more preferable. D-sorbitol, saccharose, and reduced starch syrup are even more preferable since they have a buffer effect within an appropriate pH range and are inexpensive.

These non-reducing sugars may be used alone or in combination of two or more thereof. The content of the nonreducing sugar in the developer is preferably from 0.1 mass % to 30 mass %, more preferably from 1 mass % to 20 mass % with respect to the total amount of the developer.

The base combined with the non-reducing sugar(s) may be an alkali agent that has been conventionally known. Examples thereof include inorganic alkali agents such as sodium hydroxide, potassium hydroxide, lithium hydroxide, trisodium phosphate, tripotassium phosphate, triammonium phosphate, disodium phosphate, dipotassium phosphate, diammonium phosphate, sodium carbonate, potassium carbonate, ammonium carbonate, sodium hydrogencarbonate, potassium hydrogencarbonate, ammonium hydrogencarbonate, sodium borate, potassium borate or ammonium borate; and organic alkali agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, or pyridine.

The alkali agent may be used singly or in combination of two or more. Among the alkali agents, sodium hydroxide and potassium hydroxide are preferable. The reason is that pH adjustment can be made in a wide pH range by regulating the amount of the alkali agent to be added to the non-reducing sugar. Also, trisodium phosphate, sodium carbonate, potassium carbonate or the like itself has a buffer action and are hence preferable.

In the case where an automatic developing machine is used to perform development, an aqueous solution (or, replenisher) having a higher alkali strength than that of the developer can be added to the developer. It is known that this enables a great number of photosensitive plates to be processed without replacing the developer in the developing tank over a long period of time. This replenishing manner is also preferably used in the invention.

If necessary, various surfactants or organic solvents can be incorporated into the developer and the replenisher in order to promote or suppress developability, disperse scum generated during development, and enhance the ink-affinity of image areas for the printing plate.

Preferable examples of the surfactant include anionic surfactants, cationic surfactants, nonionic surfactants and amphoteric surfactants. If necessary, the following may be added to the developer and the replenisher: a reducing agent (such as hydroquinone, resorcin, a sodium or potassium salt of an inorganic acid such as sulfurous acid or hydrogen sulfite acid), an organic carboxylic acid, a defoaming agent and a water softener.

The printing plate developed with the developer and replenisher described above is subsequently subjected to post-treatments with washing water, a rinse solution containing a surfactant and other components, and a desensitizing solution containing gum arabic and a starch derivative. Various combinations of these treatments may be employed for the post-treatment when the planographic printing plate precursor of the invention is used for forming a planographic printing plate.

In recent years, automatic developing machines for o plate precursors have been widely used in order to rationalize and standardize plate-making processes in the plate-making and printing industries. These automatic developing machines are generally made up of a developing section and a post-processing section, and include a device for conveying printing plate precursors, various treating solution tanks, and spray devices. These machines are machines for spraying respective treating solutions, which are pumped up, onto an exposed printing plate through spray nozzles, for development, while the printing plate is being transported horizontally.

Recently, a method has also attracted attention in which a printing plate precursor is immersed in treating solution tanks filled with treating solutions and conveyed by means of in-liquid guide rolls. Such automatic processing can be performed while replenishers are being replenished into the respective treating solutions in accordance with the amounts to be treated, operating times, and other factors.

A so-called disposable processing method can also be used, in which treatments are conducted with the use of unused treating solutions.

A method of processing the planographic printing plate precursor of the invention will be explained. In the case where unnecessary image portions are present on a planographic printing plate obtained by exposing imagewise to light a planographic printing plate precursor to which the invention is applied, developing the exposed precursor, and subjecting the developed precursor to water-washing and/or rinsing and/or desensitizing treatment(s), the unnecessary image portions can be erased. The erasing is preferably performed by applying an erasing solution to the unnecessary image portions, and allowing to stand the printing plate for a given time, and washing the plate with water, as described in, for example, JP-B No. 2-13293. This erasing may also be performed by a method of radiating the unnecessary image portions with actinic rays guided through optical fibers, and then developing the plate, as described in JP-A No. 5-174842.

The planographic printing plate obtained as described above is, if desired, coated with a desensitizing gum, and subsequently the plate can be made available for printing. When it is desired to make a planographic printing plate with a higher degree of printing durability, a burning treatment can be applied to the planographic printing plate.

In the case where the planographic printing plate is subjected to the burning treatment, it is preferable that the plate is treated with a counter-etching solution before the burning treatment is conducted as described in JP-B No. 61-2518, or JP-A Nos. 55-28062, 62-31859 or 61-159655.

Examples of the method of the counter-etching treatment include: a method of applying the counter-etching solution onto the planographic printing plate with a sponge or absorbent cotton infiltrated with the solution; a method of immersing the planographic printing plate in a vat filled with the counter-etching solution; and a method of applying the counter-etching solution to the planographic printing plate with an automatic coater. When the amount of solution applied is made uniform with a squeegee or a squeegee roller after application, a better result may be obtained.

In general, the amount of the counter-etching solution applied is suitably from 0.03 g/m² to 0.8 g/m² (dry mass). If necessary, the planographic printing plate onto which the counter-etching solution is applied may be dried, and then the plate is heated to a high temperature by means of a burning processor (for example, a burning processor BP-1300 (trade name) available from FUJIFILM Corporation) or the like. In this case, the heating temperature and the heating time, which may depend on the kind of components forming the image, are preferably from 180° C. to 300° C. and from 1 minute to 20 minutes.

If necessary, a planographic printing plate subjected to the burning treatment can be further subjected to treatments, such as a water-washing treatment and gum coating, which are usually used. However, in the case where a counter-etching solution containing a water soluble polymer compound or the like is used, the so-called desensitizing treatment (for example, gum coating) may be omitted. The planographic printing plate obtained by such treatments can be applied to an offset printing machine or the like, and can be used for printing on a great number of sheets.

Hereinafter, aspects of the invention will be exemplified.
<1> A planographic printing plate precursor comprising a hydrophilic support having a surface roughness (Ra) in a range of from 0.45 to 0.60, and, on the support, a recording layer containing a phenolic resin, an infrared absorber and a polymer having at least one selected from the group consisting of a structural unit represented by the following formula (I) and a structural unit represented by the following formula (II):

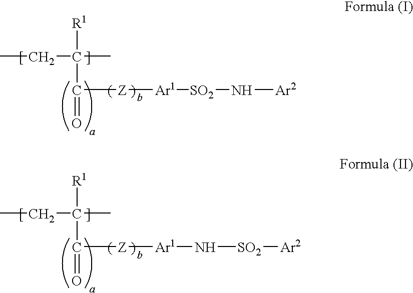

wherein, in formula (I) and formula (II): R¹ represents a hydrogen atom or an alkyl group; z represents —O— or —NR²— wherein R² represents a hydrogen atom, an alkyl group, an alkenyl group or an alkynyl group; Ar¹ and Ar² each independently represent an aromatic group, and at least one of Ar¹ and Ar² represents a heteroaromatic group; and a and b each independently represent 0 or 1.
<2> The planographic printing plate precursor of <1>, wherein the recording layer comprises a lower recording layer which is provided in closest proximity to the support and contains the polymer having at least one selected from the group consisting of a structural unit represented by formula (I) and a structural unit represented by formula (II), and an upper recording layer which contains a phenolic resin and an infrared absorber, the solubility of the upper recording layer with respect to an aqueous alkaline solution increasing upon exposure to an infrared laser beam.
<3> The planographic printing plate precursor of <2>, wherein the lower recording layer further contains an alkali-soluble polymer which has a slower dissolution speed in an aqueous alkaline solution than that of the polymer having at least one selected from the group consisting of a structural unit represented by formula (I) and a structural unit represented by formula (II), and which is incompatible with the polymer.
<4> The planographic printing plate precursor of <3>, wherein the ratio by weight of the polymer including at least one selected from the structural unit represented by formula (I) and the structural unit represented by formula (II) to the alkali-soluble polymer is in a range of from 95:5 to 60:4.
<5> The planographic printing plate precursor of <3> or <4>, wherein the alkali-soluble polymer is a novolak resin.

### EXAMPLES

The invention will be explained by way of examples, which, however, are not intended to limit the scope of the invention.

[Preparation of Exemplified Monomers Used for Specific Polymers]

Exemplified Monomers (1), (2), (8), (9) and (13) used for forming the specific polymers according to the invention can be synthesized using the methods described in Hofmann et al., Markromoleculare Cheme, vol. 177, pp. 1791-1813 (1976), and persons skilled in the art can easily obtain similar monomers through selection of some different starting materials.

### <Synthesis of Exemplified Monomer (11)>

Exemplified Monomer (11) can be synthesized using a method similar to the method described in Kang and Bae, Journal of Controlled Release, vol. 80, pp. 145-155. Details of the synthesis method are as follows.

4-amino-N-(6-methoxy-3-pyridazinyl)-benzosulfonamide in an amount of 10 g (35.6 mmol) was dispersed and dissolved in 120 ml of acetonitrile, and thereto was added a solution prepared by dissolving 1.42 g (35.6 mmol) of sodium hydroxide in 30 ml of water. The reactant solution thus prepared was cooled to −10° C., and the reaction was allowed to continue for 1 hour in a reaction vessel at ordinary temperatures. To the reaction solution obtained, 10 mg of BHT was added. And the resulting mixture was dried under normal atmospheric pressure. The oily residue thus obtained was dissolved in a mixture of 150 ml of methylene chloride and 100 ml of 2N HCl, and the resultant product was separated by using 50 ml of methylene chloride, 520 ml of 2N HCl and 100 ml of water, dried with MgSO₄ and then refluxed under normal atmospheric pressure. The thus obtained synthesis product was purified by column chromatography. Thus, 2.39 g of Exemplified monomer (11) was obtained (in a 19% yield).

<Synthesis of Exemplified Monomer (4)>

Exemplified Monomer (4) can be synthesized by a method similar to the method by which Exemplified Monomer (11) is synthesized, except that acryloyl chloride is used in place of methacryloyl chloride.

4-amino-N-(2,6-dimethyl-4-pyrimidinyl)-benzosulfonamide in an amount of 24.9 g (89.5 mmol) was dispersed and dissolved in 500 ml of acetonitrile, and thereto was added a solution prepared by dissolving 8.10 g (89.5 mmol) of potassium hydroxide in 75 ml of water. The reactant solution thus prepared was cooled to 0° C., and the reaction was allowed to continue for 14 hours in a reaction vessel at ordinary temperatures. A small amount of precipitate formed was filtered off. The resulting reaction solution was mixed with 25 mg of BHT, and dried under normal atmospheric pressure. The residue thus obtained was dissolved in 350 ml of refluxing methanol. After cooling to room temperature, the methanol solution was added to 1.6 liter of a 1:1 mixture of hexane and methyl-t-butyl ester. The resulting mixture was filtered and dried. The synthesis product thus obtained was purified by column chromatography to give Exemplified Monomer (4).

<Synthesis of Exemplified Monomer (10)>
1. Synthesis of 4-Amino-N-2-Pyrimidylbenzenesulfonamide as Intermediate

4-acetoamino-benzosulfonyl chloride in an amount of 288.75 g (1.21 moles) and 2-aminopyrimidine in an amount of 113.8 g (1.21 moles) were dispersed and dissolved in 1350 ml of acetonitrile. Thereto, was added 105.2 g (1.33 moles) of pyridine over at least 5 minutes. The temperature of the resulting mixture was raised to 60° C. Reaction was allowed to continue for 2 hours at 60° C. Thereafter, the reaction solution was cooled. Then, N-{4-[(2-pyrimidinylamino)sulfonyl]phenyl}acetamide precipitated in part out of the intermediate was filtered off. A second product was subjected to filtration under reduced pressure, and isolated by evaporation. The synthesis product obtained was treated with 1,500 ml of ice-cold water. The second product was treated with 1,500 ml of water at 40° C. N-{4-[(2-pyrimidinylamino)sulfonyl]phenyl} acetamide thus produced was filtered off. Thus, 155.9 g of N-{4-[(2-pyrimidinylamino)sulfonyl]phenyl} acetamide was obtained (yield: 55%).

The isolated N-{4-[(2-pyrimidinylamino)sulfonyl]phenyl}acetamide was dissolved in 2.5 liter of a 1:1 mixture of ethanol and 1-methoxy-2-propanol. Thereto, was added an aqueous solution of 105 g (2.66 moles) of sodium hydroxide, and the resulting mixture was refluxed for one hour. Then, the mixture was cooled to room temperature, and the solvents were removed under reduced pressure. The reaction product was dissolved in 1,300 ml of water, and adjusted to the acidity of pH 1 by addition of concentrated hydrochloric acid. The resulting solution was cooled to 0° C. The insoluble substance was removed by filtration. The water phase was extracted with 450 ml of methylene chloride three times, and adjusted to a neutral region of pH 7 by use of a 10N sodium hydroxide solution. The intermediate 4-amino-N-2-pyrimidylbenzenesulfonamide precipitated out of the resulting water phase was filtered off and dried. Thus, 93.4 g of 4-amino-N-2-pyrimidylbenzenesulfonamide was obtained (yield: 70.7%).

2. Synthesis of Exemplified Monomer (10)

To 24.9 g (0.1 mole) of the thus obtained

4-amino-N-2-pyrimidylbenzenesulfonamide, was added 0.25 g of BHT dissolved in 400 ml of pyridine. The resulting mixture was cooled to 0° C. Thereto, was added dropwise 12.54 g (0.12 mole) of methacryloyl chloride. The reaction was allowed to continue for 1 hour under the temperature condition of 0-5° C. Thereafter, the reaction was allowed to continue overnight at ordinary temperature. The solvent was removed under reduced pressure, and the product was added to a 1:1 mixture of ethanol and water.

This crude product was filtered off, and dried. The residue obtained was refluxed in a 1:1 mixture of acetone and water. These operations were repeated twice, and the product was filtered off and dried. Thus, 16.3 g of Exemplified Monomer (10) was obtained (yield: 49 %).

Exemplified Monomers (5), (6) and (7) can also be synthesized under the reaction scheme similar to the above.

<Synthesis of Specific Polymer (1)>

In a 250-ml reaction vessel, were placed 160 mmol of Exemplified Monomer (1) having a sulfonamide group, 20.6 g (132 mmol) of benzylacetamide, 2.31 g (32 mmol) of acrylic acid and 104 g of γ-butyrolactone, and the resulting mixture was heated up to 140° C. while being stirred at 200 rpm. This reaction was conducted under a circulating current of nitrogen. After the solid substance was dissolved, the temperature of the reaction vessel was lowered to 100° C. Thereto, were added in sequence 0.37 ml of TRIGONOX DC50 ((trade name) manufactured by Akzo Nobel Corporate) and a solution prepared by dissolving 1.48 ml of TRIGONOX 141 ((trade name) manufactured by Akzo Nobel Corporate) in 3.66 ml of butyrolactone. After the initiation of reaction, the reaction vessel temperature was raised to 143° C., and thereto was added 1.87 ml of TRIGONOX DC50 over at least two hours. The reaction of the mixture of the reactants was conducted for 2 hours at 140° C. while being stirred at 400 rpm. The temperature of the resulting reaction mixture was lowered to 120° C., and the stirring condition was increased to 500 rpm. Thereto, was added 86.8 ml of 1-methyl-2-propanol, and the temperature of the resulting solution was cooled to room temperature.

The polymer structure was ascertained in terms of polystyrene by ¹H-NMR spectrography and size exclusion chromatography using dimethylacetamide/0.21% LiCl as a mark and a mixing column.

With respect to the molecular weight of Specific Polymer (1), Mn was found to be 20,500, Mw 66,000, and PD 3.05.

<Syntheses of Specific Polymers (2), (4), (5) and (6)>

In the following synthesis method, Exemplified Monomer (1) as a starting material was used for synthesizing Specific Polymer (2), Exemplified Monomer (3) as a starting material was used for synthesizing Specific Polymer (4), Exemplified Monomer (7) as a starting material was used for synthesizing Specific Polymer (5), and Exemplified Monomer (5) as a starting material was used for synthesizing Specific Polymer (6), respectively.

In a 250-ml reaction vessel, were placed 162 mmol of the monomer specified above as a starting material, 21.3 g (132 mmol) of benzylacetamide, 0.43 g (6 mmol) of acrylic acid and 103 g of γ-butyrolactone, and the resulting mixture was heated up to 140° C. while being stirred at 200 rpm. This reaction was conducted under a circulating current of nitrogen. After the solid matter was dissolved, the temperature of the reaction vessel was lowered to 100° C. Thereto, were added 0.35 ml of TRIGONOX DC50 ((trade name) manufactured by Akzo Nobel Corporate) and a solution prepared by dissolving 1.39 ml of TRIGONOX 141 ((trade name) manufactured by Akzo Nobel Corporate) in 3.43 ml of butyrolactone in sequence. After the initiation of reaction, the temperature of the reaction vessel was raised to 140° C., and thereto was added 1.75 ml of TRIGONOX DC50 over at least two hours. The reaction of the mixture of reactants was conducted for 2 hours at 145° C. while being stirred at 400 rpm. The temperature of the resulting reaction mixture was lowered to 120° C., and the stirring condition was increased to 500 rpm. Thereto, was added 85.7 ml of 1-methyl-2-propanol, and the temperature of the resulting solution was cooled to room temperature.

The structure of each polymer was ascertained by the same techniques as that of Specific Polymer (1). Results obtained are shown below.

| | |
|---|---|
| Specific Polymer (2) | Mn: 28,000, Mw: 66,000, PD: 2.84 |
| Specific Polymer (4) | Mn: 34,000, Mw: 162,000, PD: 4.76 |
| Specific Polymer (5) | Mn: 22,000, Mw: 44,000, PD: 1.91 |
| Specific Polymer (6) | Mn: 23,500, Mw: 55,000, PD: 2.24 |

<Syntheses of Specific Polymers (3) and (7)>

In the following synthetic method, Exemplified Monomer (1) as a starting material was used for synthesizing Specific Polymer (3), and Exemplified Monomer (8) as a starting material was used for synthesizing Specific Polymer (7), respectively.

In a 250-ml reaction vessel, were placed 132 mmol of the monomer specified above as a starting material, 25.0 g (160 mmol) of benzylacetamide, 2.31 g (32 mmol) of acrylic acid and 104 g of γ-butyrolactone, and the resulting mixture was heated up to 140° C. while being stirred at 200 rpm. This reaction was conducted under a circulating current of nitrogen. After the solid substance was dissolved, the temperature of the reaction vessel was lowered to 100° C. Thereto, were added 0.37 ml of TRIGONOX DC50 ((trade name) manufactured by Akzo Nobel Corporate) and a solution prepared by dissolving 1.87 ml of TRIGONOX 141 ((trade name) manufactured by Akzo Nobel Corporate) in 3.43 ml of butyrolactone in sequence. After the initiation of reaction, the temperature of the reaction vessel was raised to 140° C., and thereto was added 1.48 ml of TRIGONOX DC50 over at least two hours. The reaction of the mixture of reactants was conducted for 2 hours at 140° C. while being stirred at 400 rpm. The temperature of the resulting reaction mixture was decreased to 120° C., and the stirring condition was increased to 500 rpm. Thereto, was added 86.8 ml of 1-methyl-2-propanol, and the temperature of the resulting solution was cooled to room temperature.

The structure of each polymer was ascertained by the same techniques as that of Specific Polymer (1). Results obtained are shown below.

| | |
|---|---|
| Specific Polymer (3) | Mn: 30,000, Mw: 85,000, PD: 2.78 |
| Specific Polymer (7) | Mn: 17,000, Mw: 29,000, PD: 1.67 |

### Examples 1 to 10 and Comparative Examples 1 to 2

<Preparation of Support (A) for the Planographic Printing Plate>

An aluminum alloy, which contains 0.06 mass % of Si, 0.30 mass % of Fe, 0.026 mass % of Cu, 0.001 mass % of Mn, 0.001 mass % of Mg, 0.001 mass % of Zn and 0.02 mass % of Ti, the balance being Al and inevitable impurities, was used to prepare a molten metal. The molten metal was then subjected to molten metal treatment, filtered and formed into an ingot of 500 mm in thickness and 1,200 mm in width by a DC casting method. After the surface was planed off in an average thickness of 10 mm with a slab milling machine, the ingot was maintained at a temperature of 550° C. for about 5 hours, and when the temperature was lowered to 400° C., the ingot was formed into a rolled plate of 2.7 mm in thickness with a hot rolling mill. Then, the plate was subjected to heat treatment at 500° C. with a continuous annealing device and finished with cold rolling to give a plate of 0.24 mm in thickness as an aluminum plate according to JIS 1050. In addition, the average crystalline particle size of thus obtained aluminum was 50 μm in minor axis and 300 μm in major axis. This aluminum plate was formed into a plate of 1030 mm in width, and then subjected to the following surface treatment.

<Surface Treatment>

The following treatments (a) to (k) were successively conducted in the surface treatment. After each treatment and water washing, remaining liquid was removed with nip rollers.

(a) Mechanical Surface Roughening Treatment

The surface of the aluminum plate was subjected to a mechanical surface roughening treatment with a rotating roller-shaped nylon brush while the plate was supplied with an aqueous suspension of an abrasive (Pumice) having a specific gravity of 1.12 as an abrasive slurry. The average particle diameter of the abrasive was 30 μm, and the maximum particle diameter was 100 μm. The nylon brush was made of 6.10 nylon, the length of the brush bristle was 45 mm, and the diameter of the brush bristle was 0.3 mm. The nylon brush had bristles arranged densely in holes in a stainless steel cylinder of φ300 mm. Three rotating brushes were used. The distance between two supporting rollers (φ200 nm) under the brushes was 300 mm. The brush rollers were pressed against the aluminum plate until the load of a driving motor for rotating the brushes was increased by 7 kW relative to the load before the brush rollers were pressed against the aluminum plate. The direction of rotation of the brushes was the same as the direction of movement of the aluminum plate. The number of revolutions of the brushes was 200 rpm.

(b) Alkali Etching Treatment

The aluminum plate obtained above was subjected to an etching treatment by spraying with an aqueous solution of sodium hydroxide at a concentration of 26 mass % and aluminum ions at a concentration of 6.5 mass % at a temperature of 70° C., whereby the aluminum plate was dissolved in an amount of 10 g/m². Thereafter, the aluminum plate was washed by spraying with water.

(c) Desmut Treatment

The aluminum plate was subjected to a desmut treatment by spraying with an aqueous solution (containing 0.5 mass % of aluminum ion) of 1 mass % of nitric acid at a temperature of 30° C. and then washed by spraying with water. The aqueous solution of nitric acid used in the desmut treatment was the waste liquid resulted from the process of the electrochemical surface roughening treatment with an alternating current in an aqueous solution of nitric acid.

(d) Electrochemical Surface Roughening Treatment

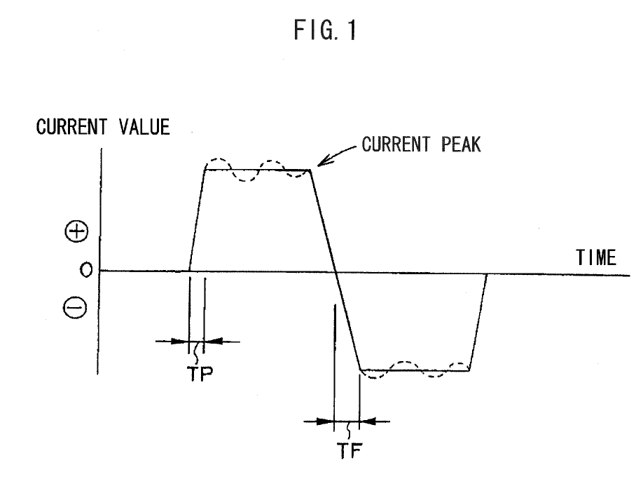

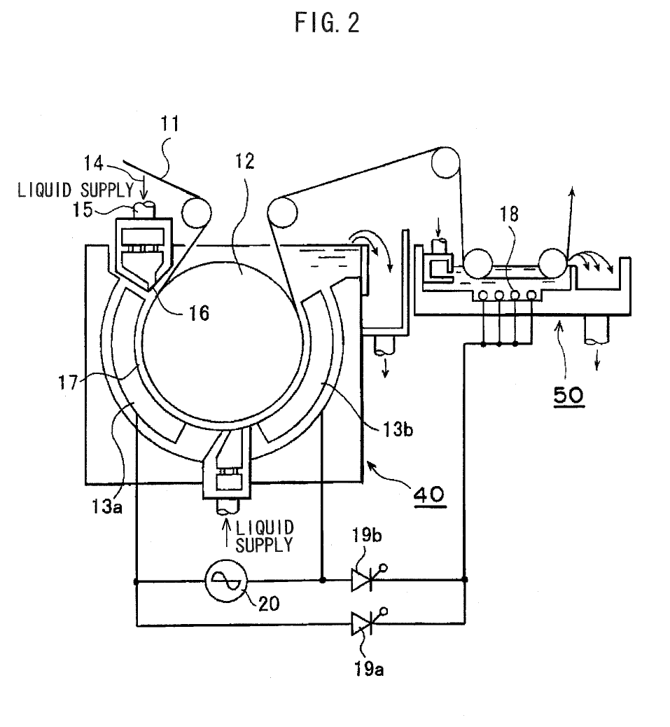

The plate was subjected to a continuous electrochemical surface roughening treatment with an alternating voltage of 60 Hz. The electrolyte used was 10.5 g/L aqueous nitric acid solution (containing 5 g/L of aluminum ion and 0.007 mass % of ammonium ion) at a temperature of 50° C. The electrochemical surface roughening treatment was carried out with a carbon electrode as a counter electrode wherein the alternating current power source waveform had a waveform as shown in FIG. 1, the time required for the electric current to reach from 0 to the peak was 0.8 msec., the duty ratio was 1:1, and a trapezoidal rectangular wave alternating current was used. Ferrite was used as an auxiliary anode. The electrolyte chamber used was as shown in FIG. 2. In FIG. 2, 11 denotes an aluminum plate, 12 denotes a radial drum roller, 13a and 13b each denote a main electrode, 14 denotes an electrolytic treatment liquid, 15 denotes an electrolytic liquid supplying opening, 16 denotes a slit, 17 denotes an electrolytic liquid passage, 18 denotes an auxiliary anode; 19a and 19b each denote a thyristor, 20 denotes an alternating current power supply, 40 denotes a main electrolytic bath, and 50 denotes an auxiliary anode bath. A radial cell type electrolytic chamber was used.

The current density was 30 A/dm² in terms of the electric current peak, and the electrical quantity was 220 C/dm² in terms of the total electrical quantity when the aluminum plate was an anode. 5% of the electric current from the power source was fed through the auxiliary anode. Thereafter, the plate was washed by spraying with water.

(e) Alkali Etching Treatment

The aluminum plate was subjected to an etching treatment by spraying with an aqueous solution of sodium hydroxide at a concentration of 26 mass % and aluminum ions at a concentration of 6.5 mass % at a temperature of 32° C., whereby the aluminum plate was dissolved in an amount of 0.50 g/m². Smut components containing aluminum hydroxide as a main component formed by the electrochemical surface roughening treatment using the alternating current in the previous stage, were removed, and the edges of the pits formed were dissolved to smooth the edge. Thereafter, washing by spraying with water was carried out.

(f) Desmut Treatment

The aluminum plate was subjected to a desmut treatment by spraying with an aqueous solution of 15 mass % of nitric acid (containing 4.5 mass % of aluminum ions) at a temperature of 30° C. and then washed by spraying with water. The aqueous solution of nitric acid used in the desmut treatment was the waste liquid resulted from the process of the electrochemical surface roughening treatment with an alternating current in an aqueous solution of nitric acid.

(g) Electrochemical Surface Roughening Treatment

The plate was subjected to continuous electrochemical surface roughening treatment with an alternating voltage of 60 Hz. The electrolyte used an aqueous solution containing 5.0 g/L of hydrochloric acid (containing 5 g/L of aluminum ion) at a temperature of 35° C. The electrochemical surface roughening treatment was carried out with a carbon electrode as a counter electrode wherein the alternating current power source waveform the time TP required for the electric current to reach from 0 to the peak was 0.8 msec., the duty ratio was 1:1, and a trapezoidal rectangular wave alternating current was used. Ferrite was used as an auxiliary anode. A radial cell type electrolytic chamber was used.

The current density was 25 A/dm² in terms of the electric current peak, and the electrical quantity was 50 C/dm² in terms of the total electrical quantity when the aluminum plate was an anode. Thereafter, the plate was washed by spraying with water.

(h) Alkali Etching Treatment

The aluminum plate was subjected to an etching treatment by spraying with an aqueous solution of sodium hydroxide at a concentration of 26 mass % and aluminum ions at a concentration of 6.5 mass % at a temperature of 32° C., whereby the aluminum plate was dissolved in an amount of 0.10 g/m². Smut components containing aluminum hydroxide as a main component formed by the electrochemical surface roughening treatment using the alternating current in the previous stage, were removed, and the edges of the pits formed were dissolved to smooth the edge. Thereafter, washing by spraying with water was carried out.

(i) Desmut Treatment

The aluminum plate was subjected to desmut treatment by spraying with an aqueous solution of 25 mass % of sulfuric acid (containing 0.5 mass % aluminum ions) at a temperature of 60° C. and then washed by spraying with water.

(j) Anodizing Treatment

Anodizing treatment was carried out with an anodizing apparatus for two-step current feeding which has a structure with first and second electrolytic zones of 6 m in length for each, first and second current feeding zones of 3 m in length for each, and first and second current feeding zones of 2.4 m in length for each. The electrolytes supplied to the first and second electrolytic zones were sulfuric acid. Both the electrolytes contained 50 g/L of sulfuric acid (containing 0.5 mass % of aluminum ions) at a temperature of 20° C. Thereafter, washing by spraying with water was carried out. The final anodized coating was 2.7 g/m².

(k) Alkali Metal Silicate Treatment

The aluminum support obtained by the anodizing treatment was subjected to alkali metal silicate treatment (silicate treatment) being immersed in an aqueous solution of 1 mass % of disodium trisilicate at a liquid temperature of 30° C. for 10 seconds. Thereafter, the aluminum support was washed by spraying with well water to obtain a support (A) for planographic printing plate with a silicate-hydrophilicized surface. As a result of measurement of the surface roughness (Ra) of the support by the aforementioned method, Ra was 0.54 μm.

<Preparation of Support (B) For Planographic Printing Plate>

A support (B) for planographic printing plate was obtained in a manner similar to the method of preparing the support (A) in the preparation of the support for planographic printing plate (A) except that the number of revolutions of the brush was changed to 280 rpm from 200 rpm in the mechanical surface roughening treatment (a). The surface roughness (Ra) of the support measured according to the above method was 0.56 μm.

<Preparation of Support (C) For Planographic Printing Plate>

An aluminum plate as stipulated in JIS A 1050-H18 with a thickness of 0.3 mm was subjected to a surface treatment by performing the following treatments of (a)-(g), consecutively.

(a) Etching Treatment (First Etching Treatment) in Aqueous Alkaline Solution

The aluminum plate was subjected to an etching treatment by being immersed in an aqueous solution containing sodium hydroxide at a concentration of 27 mass % and an aluminum ion at a concentration of 6.5 mass % at 70° C. The concentration of the aluminum ion was adjusted with the use of sodium aluminate. The amount of etching of the surface to be subjected to the electrolytic surface roughening treatment later of the aluminum was 1 g/m². Subsequently, the aluminum plate was washed.

(b) Desmut Treatment (First Desmut Treatment) in Aqueous Acidic Solution

Next, a desmut treatment was performed in an aqueous acidic solution. The aqueous acidic solution used in the desmut treatment was an aqueous solution containing sulfuric acid of 150 g/L (liquid temperature of 35° C.), and the time of the desmut treatment by immersion was 5 seconds. Thereafter, washing treatment was performed.

(c) Electrolytic Surface Roughening Treatment in Aqueous Hydrochloric Acid

Next, an electrolytic surface roughening treatment was performed with the use of an electrolytic solution containing hydrochloric acid at a concentration of 15 g/L, an aluminum ion at a concentration of 14 g/L and sulfuric acid at a concentration of 3 g/L by applying an alternating current. The temperature of the electrolytic solution was 35° C. The concentration of the aluminum ion was adjusted by adding aluminum chloride.

The waveform of the alternating current was a symmetrical sine wave on the positive and negative sides. The frequency of the alternating current was 50 Hz, the duty was 0.5 and the current density was 75 A/dm² at the peak current value of the alternating current waveform. The quantity of electricity was 500 C/dm² in terms of the total quantity of electricity in association with the anodic reaction of the aluminum plate. The electrolytic treatment was performed by dividing into four treatments with intervals of four seconds between the current applications of 125 C/dm², respectively, to total 500 C/dm². A carbon electrode as a counter electrode of the aluminum plate was used. Thereafter, washing treatment was performed.

(d) Etching Treatment (Second Etching Treatment) in Aqueous Alkaline Solution

The aluminum plate was subjected to an etching treatment by being immersed in an aqueous solution containing sodium hydroxide at a concentration of 5 mass % and an aluminum ion at a concentration of 0.5 mass % at 35° C., so as to be the amount of etching of 0.1 g/m² of the surface subjected to the surface roughening treatment of the aluminum plate. The concentration of the aluminum ion was adjusted with the use of sodium aluminate. Subsequently, washing was performed.

(e) Desmut Treatment (Second Desmut Treatment) in Aqueous Acidic Solution

Next, a desmut treatment was performed. As the aqueous acidic solution used for the desmut treatment, a waste solution (aluminum ion of 5.0 g/L dissolved in aqueous solution of sulfuric acid of 170 g/L) resulting from the anodic oxidation treatment was used by immersing the aluminum plate in the solution at a liquid temperature of 30° C. for five seconds.

(f) Anodic Oxidation Treatment

Next, an anodic oxidation treatment was preformed by using an anodizing apparatus.

As the electrolytic solution, an electrolytic solution formed by dissolving aluminum sulfate at a concentration of 5 g/L of aluminum ion in an aqueous sulfuric acid solution at a concentration of 170 g/L was used (temperature of 45° C.). The anodic oxidation treatment was performed at a current density of 30 A/dm² to form an anodized layer having an amount of 2.7 g/m². A carbon electrode as a counter electrode of the aluminum plate was used. Thereafter, washing treatment was performed.

(g) Hydrophilicizing Treatment

The aluminum plate was immersed in an aqueous solution of 1.0 mass % of disodium trisilicate (liquid temperature of 22° C.) for 8 seconds. The quantity of Si on the surface of the aluminum plate measured by an X-ray fluorescence spectrometer was 3.5 mg/m².

Thereafter, the aluminum plate was washed, squeezed with a nip roller and further dried by blowing air at a temperature of 90° C. for 10 second to obtain a support (C) for the planographic printing plate according to the invention. As a result of measurement of the surface roughness (Ra) of the support by the aforementioned method, Ra was 0.47 μm.

<Preparation of Comparative Support (D) for Planographic Printing Plate>

After an aluminum plate according to JIS 1050 having a thickness of 0.30 mm was cut into a width of 1,030 mm, the aluminum plate was subjected to the following surface treatment.

<Surface Treatment>

The following treatments (a)-(d) are conducted successively. After each treatment and washing, remaining liquid was removed with nip rollers.

(a) Degreasing Treatment

An aluminum plate was immersed in an aqueous sodium hydroxide solution (34 g/L) at 70° C. for 6 second, and washed with ion exchange water for 3.6 seconds to be degreased.

(b) Electrochemical Surface Roughening Treatment

An electrochemical surface roughening treatment was continuously performed by applying an alternating current of 60 Hz for 8 seconds. The electrolytic solution containing hydrochloric acid at a concentration of 15 g/L (containing 5 g/L of aluminum ion and 15 g/L of sulfuric acid ion) at a liquid temperature of 37° C. The current density was 100 A/dm² at the peak current value. Thereafter, washing was conducted with spraying.

Desmut Treatment

An etching treatment was conducted for a desmut treatment by immersing the aluminum plate in an aqueous sulfuric acid (145 g/L) solution at 80° C., followed by washing with ion exchange water for four seconds.

(d) Anodic Oxidation Treatment

An anodic oxidation treatment was conducted by the use of an anodic oxidizing apparatus. As the electrolytic solution supplied to the electrolytic section, sulfuric acid was used. The electrolytic solution contains sulfuric acid at a concentration of 145 g/L, and used at a temperature of 80° C. and a current density of 25 A/dm². The anodic oxidation treatment was conducted under this condition for 10 seconds. Thereafter, the aluminum plate was immersed in ion exchange water for 7 seconds for washing, and subjected to a post-treatment by immersing the aluminum plate in an aqueous solution of polyvinyl sulfonic acid (2.2 g/L) at 70° C. for four seconds, followed by immersing the aluminum plate in ion exchange water for 3.5 seconds for washing. The washed aluminum plate was dried at 120° C. for 7 seconds to obtain a comparative support (D) for planographic printing plate. The quantity of the oxidized layer finally obtained was 3.0 g/m². As a result of measurement of the surface roughness (Ra) of the support by the aforementioned method, Ra was 0.3 μm.

<Formation of Undercoat Layer>

The following coating liquid as described below was coated on the supports (A)-(D) for planographic printing plate obtained in the above, and was dried at 80° C. for 15 second to form a coated layer. The amount of the coating (undercoat layer) after drying was 15 mg/m².

Formulation of Undercoat Liquid

| | | |
|---|---|---|
| Polymer compound 1 (weight average | 0.3 | g |
| molecular weight: 28,000) | | |
| Methanol | 100 | g |
| Water | 1 | g |

| | |
|---|---|
| Polymer compound 1 | |
| 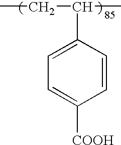 | 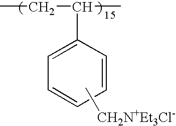 |

<Formation of Positive-Working Recording Layer>

The coating liquid for the lower recording layer having the following formulation was applied to the thus obtained support (as recited in Table 1) for planographic printing plate such that the application amount thereof was 0.85 g/m², and then dried at 140° C. for 50 seconds with PERFECT OVEN PH200 (trade name, manufactured by TABAI) by setting the level of wind control thereof to seven. Thereafter, the above coating liquid for the upper recording layer having the following formulation was applied to the resulting coating layer such that the application amount thereof was 0.15 g/m², and then dried at 120° C. for 1 minute, to obtain planographic printing plate precursors of Examples 1 to 10 and Comparative Examples 1 to 2.

<Coating Composition For Lower Recording Layer>

| | | |
|---|---|---|
| Polymer (one or two kinds of polymers shown in Table 1) | 2.15 | g |
| (content of each polymer in Table 1 is | | |
| expressed as a mass, with respect to | | |
| the total amount of polymers being taken as 100) | | |
| Cyanine dye A | 0.13 | g |
| 4,4′-Bishydroxyphenylsulfone | 0.11 | g |
| Tetrahydrophthalic anhydride | 0.15 | g |
| p-Toluenesulfonic acid | 0.01 | g |
| 3-Methoxy-4-diazodiphenylamine hexafluorophosphate | 0.03 | g |
| Crystal Violet (the counter anion of which | 0.10 | g |
| is replaced with naphthalenesulfonic acid) | | |
| Fluorine-containing surfactant F-780-F | 0.035 | g |
| (manufactured by DIC Corporation) | | |
| Methyl ethyl ketone | 24 | g |
| 2-Methoxy-1-propanol | 13 | g |
| γ-Butyrolactone | 14 | g |

Cyanine Dye A

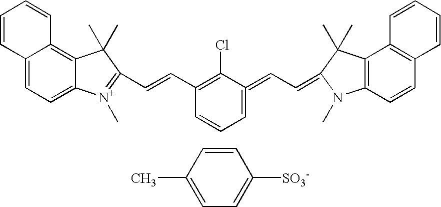

TABLE 1

| | Support for | Specific | Specific | Specific | Specific | Specific | Specific | Specific | | | |
|---|---|---|---|---|---|---|---|---|---|---|---|
| | Planographic | Polymer | Polymer | Polymer | Polymer | Polymer | Polymer | Polymer | Novolak | Novolak | Novolak |
| | Printing Plate | (1) | (2) | (3) | (4) | (5) | (6) | (7) | (A) | (B) | (C) |
| Example 1 | (A) | 100 | — | — | — | — | — | — | — | — | — |
| | Ra 0.54 μm | | | | | | | | | | |
| Example 2 | (A) | 95 | — | — | — | — | — | — | — | — | 5 |
| Example 3 | (A) | 75 | — | — | — | — | — | — | 25 | — | — |
| Example 4 | (A) | 65 | — | — | — | — | — | — | — | 35 | — |
| Example 5 | (A) | — | 75 | — | — | — | — | — | — | — | 25 |
| Example 6 | (A) | — | — | 70 | — | — | — | — | 30 | — | — |
| Example 7 | (A) | — | — | — | 90 | — | — | — | — | 10 | — |
| Example 8 | (A) | — | — | — | — | 65 | — | — | — | 30 | 5 |
| Example 9 | (B) | — | — | — | — | — | 60 | — | 40 | — | — |
| | Ra 0.56 μm | | | | | | | | | | |
| Example 10 | (C) | 80 | — | — | — | — | — | — | 20 | — | — |
| | Ra 0.47 μm | | | | | | | | | | |
| Comparative | (D) | 100 | — | — | — | — | — | — | — | — | — |
| Example 1 | Comparative | | | | | | | | | | |
| | Support | | | | | | | | | | |
| | Ra 0.3 μm | | | | | | | | | | |
| Comparative | (D) | — | — | — | — | — | — | 100 | — | — | — |
| Example 2 | Comparative | | | | | | | | | | |
| | Support | | | | | | | | | | |

Details of each of the polymers shown in Table 1 are as follows.
Specific Polymers (1) to (7): The specific polymers synthesized in the above manners
Novolak A: 2,5-xylenol/m-cresol/p-cresol novolak (5/55/40, weight average molecular weight: 6,500)
Novolak B: m-cresol/p-cresol novolak (60/40, weight average molecular weight: 3,500)
Novolak C: phenol/m-cresol/p-cresol novolak (20/50/30, weight average molecular weight: 5,000)

<Coating Composition For Upper Recording Layer>
m-Cresol/p-cresol novolak (m/p ratio=6/4, weight average molecular weight: 4,500, unreacted cresol content: 0.8 mass %) 0.2846 g
Cyanine dye A (of the structure illustrated hereinbefore) 0.075 g
Behenic acid amide 0.060 g
Fluorine-containing surfactant (a surfactant for improving surface property) [MEGAFACE F781F, manufactured by DIC Corporation]0.022 g
Fluorine-containing surfactant (a surfactant for improving image formability) [MEGAFACE F780 (30%), manufactured by DIC Corporation]0.120 g
Methyl ethyl ketone 15.1 g
1-Methoxy-2-propanol 7.7 g

(Evaluations of Planographic Printing Plate Precursor)

On each of the planographic printing plate precursors obtained in Examples 1 to 10 and Comparative Examples 1 to 2, evaluations of resolution, printing durability and resistance to chemicals were made as follows.

1. Evaluation of Resolution

A test pattern was imagewisely written on each of the planographic printing plate precursors obtained in Examples 1 to 10 and Comparative Examples 1 to 2, with 12,800 dpi and at the drum revolution number of 360 rpm and the output power of 10 W by the use of TRENDSETTER UHR ((trade name) manufactured by Kodak).

When writing, characters of “FUJIFILM” in Ming font were formed and written by changing the font size.

The printing plate was developed with the use of Developer DT-2 (diluted with water to form 43 mS/cm) ((trade name) manufactured by Fujifilm Corporation) placed in PS processor 940 HII ((trade name) manufactured by Fujifilm Corporation), at a liquid temperature of 30° C. and a developing time of 12 seconds.

The resolution was evaluated on the basis of the minimum font point of characters reproducible without blur. In Table 2, “2” shows that a 2 font point character is reproducible without blur.

2. Evaluation of Printing Durability

In the same manners as mentioned in the above 1, writing (exposure) and development were made on each of the planographic printing plate precursors obtained in Examples 1 to 10 and Comparative Examples 1 to 2, and thereby planographic printing plates were obtained. Printing on wood-free paper was done by means of a printing press Heidelberg KOR-D wherein each of the planographic printing plates obtained was used. The printing durability of each plate was evaluated on the basis of the number of sheets on which printing was done before the thickness of the recording layer of the printing plate was decreased to the degree of causing inking failure partially, or a so-called plate wearing. Results obtained are shown in Table 2.

3. Evaluation of Resistance to Chemicals

The resistance to chemicals was evaluated by use of the following test solutions 1 to 3 in accordance with the evaluation method and evaluation criteria described below. Results obtained are shown in Table 2.

Test Solutions
Test solution 1: EMERALD PREMIUM MXEH (available from ANCHOR)
Test solution 2: Allied Meter-X (available from ABC Chemicals)
Test solution 3: Prisco 2351 (free of phosphate, available from Prisco)

Evaluation Method

The test solutions 1 to 3 in a volume of 40 μL were dropped on different positions on the surface of the recording layer dropwisely, respectively, in each of the planographic printing plate precursors obtained. After a lapse of 3 minutes, the droplets were wiped off from the recording layer surface with cotton pads. Damages to the recording layer resulting from the test solutions were checked by visual observations in accordance with the following evaluation criteria.

Criteria
0: No damages on the recording layer surface are observed;
1: glossiness of the recording layer surface is changed;
2: slight damages on the recording layer surface (reduction in thickness) are observed;
3: severe damages on the recording layer surface are observed; and
4: the recording layer is completely dissolved.

TABLE 2

| | | Printing | Resistance to chemicals | | |
|---|---|---|---|---|---|
| | Resolution | Durability | Test-1 | Test-2 | Test-3 |
| Example 1 | 3 | 120,000 sheets | 1 | 1 | 1 |
| Example 2 | 2 | 120,000 sheets | 1 | 1 | 1 |
| Example 3 | 2 | 120,000 sheets | 1 | 1 | 1 |
| Example 4 | 2 | 120,000 sheets | 1 | 1 | 1 |
| Example 5 | 2 | 120,000 sheets | 1 | 1 | 1 |
| Example 6 | 2 | 120,000 sheets | 1 | 1 | 1 |
| Example 7 | 2 | 120,000 sheets | 1 | 1 | 1 |
| Example 8 | 2 | 120,000 sheets | 1 | 1 | 1 |
| Example 9 | 2 | 120,000 sheets | 1 | 1 | 1 |
| Example 10 | 2 | 120,000 sheets | 1 | 1 | 1 |
| Comparative | 8 | 100,000 sheets | 1 | 1 | 1 |
| Example 1 | | | | | |
| Comparative | 5 | 60,000 sheets | 3 | 4 | 3 |
| Example 2 | | | | | |

As is clear from Table 2, the planographic printing plate precursors of Examples 1 to 10 are excellent in all of the resolution (reproducibility of a high definition image), printing durability and resistance to chemicals, as compared with the planographic printing plate precursors of Comparative Examples 1 and 2, in which printing plates outside of the scope of the invention are used.

According to an aspect of the present invention, it is possible to provide a positive-working planographic printing plate precursor excellent in image reproducibility by a high definition exposure (resolution) as well as the printing durability and resistance to chemicals.

Accordingly, in particular, according to an aspect of the present invention, it is possible to improve the stability in plate-making when forming a high definition image. Further, it is also possible to obtain favorable printing durability of high definition image areas. The scope of the term “high definition images” includes an FM screen image whose use has been increasing with recent CTP application.

What is claimed is:

1. A planographic printing plate precursor comprising a hydrophilic support having a surface roughness (Ra) in a range of from 0.45 to 0.60, and, on the support, a recording layer containing a phenolic resin, an infrared absorber and a polymer having at least one selected from the group consisting of a structural unit represented by the following formula (I) and a structural unit represented by the following formula (II): 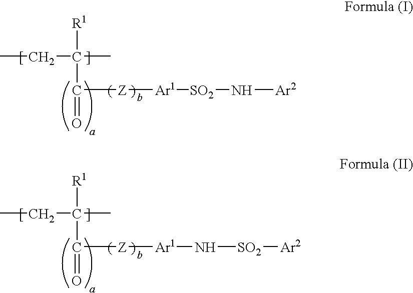
wherein, in formula (I) and formula (II): R¹ represents a hydrogen atom or an alkyl group; z represents —O— or —NR— wherein R² represents a hydrogen atom, an alkyl group, an alkenyl group or an alkynyl group; Ar¹ and Ar² each independently represent an aromatic group, and at least one of Ar¹ and Ar² represents a heteroaromatic group; and a and b each independently represent 0 or 1.

2. The planographic printing plate precursor according to claim 1, wherein the recording layer comprises a lower recording layer which is provided in closest proximity to the support and contains the polymer having at least one selected from the group consisting of a structural unit represented by formula (I) and a structural unit represented by formula (II), and an upper recording layer which contains a phenolic resin and an infrared absorber, the solubility of the upper recording layer with respect to an aqueous alkaline solution increasing upon exposure to an infrared laser beam.

3. The planographic printing plate precursor according to claim 2, wherein the lower recording layer further contains an alkali-soluble polymer which has a slower dissolution speed in an aqueous alkaline solution than that of the polymer having at least one selected from the group consisting of a structural unit represented by formula (I) and a structural unit represented by formula (II), and which is incompatible with the polymer.

4. The planographic printing plate precursor according to claim 3, wherein the ratio by weight of the polymer including at least one selected from the structural unit represented by formula (I) and the structural unit represented by formula (II) to the alkali-soluble polymer is in a range of from 95:5 to 60:4.

5. The planographic printing plate precursor according to claim 3, wherein the alkali-soluble polymer is a novolak resin.

6. The planographic printing plate precursor according to claim 4, wherein the alkali-soluble polymer is a novolak resin.
